(19) United States
(12) Patent Application Publication
(10) Pub. No.: US 2026/0076057 A1
(43) Pub. Date: Mar. 12, 2026

(54) DISPLAY DEVICE AND ELECTRONIC DEVICE INCLUDING THE SAME

(71) Applicant: Samsung Display Co., Ltd., Yongin-si (KR)

(72) Inventors: BOKWANG SONG, Yongin-si (KR); TAEKYUNG AHN, Yongin-si (KR); GEE-BUM KIM, Yongin-si (KR); KWANG SOO BAE, Yongin-si (KR)

(21) Appl. No.: 19/263,245

(22) Filed: Jul. 8, 2025

(30) Foreign Application Priority Data
Sep. 11, 2024 (KR) 10-2024-0124299

(51) Int. Cl. H10K 59/65; G06V 40/13; H10K 59/40; H10K 59/80

(52) U.S. Cl. CPC H10K 59/65; G06V 40/1318; H10K 59/40; H10K 59/873; H10K 59/8793

(57) ABSTRACT

A display device includes: a base layer; a circuit layer on the base layer; an element layer on the circuit layer and including a light emitting element and a light receiving element; an optical layer on the element layer and having a first transmission hole corresponding to the light receiving element; and a polarization layer on the optical layer and configured to have a transmission axis, wherein the first transmission hole has a shape in which a width in a direction perpendicular to the transmission axis is smaller than a width in a direction parallel to the transmission axis.

### CROSS-REFERENCE TO RELATED APPLICATION

The present application claims priority to and the benefit of Korean Patent Application No. 10-2024-0124299, filed on Sep. 11, 2024, in the Korean Intellectual Property Office, the entire disclosure of which is incorporated herein by reference.

### BACKGROUND

Aspects of some embodiments of the present disclosure described herein relate to a display device having a biometric information recognition function and an electronic device including the display device.

A display device provides various functions of organically communicating with the user such as providing information to a user by displaying an image or detecting a user input. Display devices may include a function to detect the user's biometric information.

Biometric information recognition schemes include a capacitive scheme that detects a change in capacitance between electrodes, an optical scheme that detects incident light by using an optical sensor, and an ultrasonic scheme that detects vibration by using a piezoelectric material or the like.

The above information disclosed in this Background section is only for enhancement of understanding of the background and therefore the information discussed in this Background section does not necessarily constitute prior art.

### SUMMARY

Aspects of some embodiments of the present disclosure include a display device with relatively improved biometric information recognition performance and an electronic device including the display device.

According to some embodiments, a display device includes a base layer, a circuit layer on the base layer, an element layer on the circuit layer and including a light emitting element and a light receiving element, an optical layer on the element layer and provided with a first transmission hole corresponding to the light receiving element, and a polarization layer on the optical layer and having a transmission axis.

According to some embodiments, the first transmission hole has a shape in which a width in a direction perpendicular to the transmission axis is smaller than a width in a direction parallel to the transmission axis.

According to some embodiments, a display device includes a base layer, a circuit layer on the base layer, an element layer on the circuit layer and including a light emitting element and a light receiving element, an optical layer on the element layer and provided with first transmission holes corresponding to the light receiving element, and a polarization layer on the optical layer and having a transmission axis.

According to some embodiments, the light receiving element has a shape in which a width in a direction perpendicular to the transmission axis is smaller than a width in a direction parallel to the transmission axis.

According to some embodiments, an electronic device includes a display module and a processor that controls operation of the display module. According to some embodiments, the display module includes a base layer, a circuit layer on the base layer, an element layer on the circuit layer and including a light emitting element and a light receiving element, an optical layer on the element layer and provided with a first transmission hole corresponding to the light receiving element, and a polarization layer on the optical layer and having a transmission axis.

According to some embodiments, the first transmission hole has a shape in which a width in a direction perpendicular to the transmission axis is smaller than a width in a direction parallel to the transmission axis.

### BRIEF DESCRIPTION OF THE DRAWINGS

The above and other aspects and features of embodiments according to the present disclosure will become more apparent by describing in more detail aspects of some embodiments thereof with reference to the accompanying drawings.

FIG. 1 is a perspective view of a display device, according to some embodiments of the present disclosure.

FIG. 2 is a cross-sectional view of a display device, according to some embodiments of the present disclosure.

FIG. 3 is a block diagram of a display device, according to some embodiments of the present disclosure.

FIG. 4A is a circuit diagram illustrating a pixel and a sensor, according to some embodiments of the present disclosure.

FIG. 4B is a waveform diagram for describing operations of the pixel and the sensor shown in FIG. 4A.

FIG. 5A is a plan view showing an element layer and an optical layer, according to some embodiments of the present disclosure.

FIG. 5B is an enlarged view showing a portion of FIG. 5A.

FIGS. 6A and 6B are cross-sectional views of a display device taken along a cutting line I-I′ illustrated in FIG. 5A, according to some embodiments of the present disclosure.

FIG. 7A is a cross-sectional view of a display module taken along a cutting line II-II′ shown in FIG. 5B.

FIG. 7B is a cross-sectional view of a display module taken along a cutting line III-III′ shown in FIG. 5B.

FIG. 8A is a plan view showing a first transmission hole shape of an optical layer according to a comparative example.

FIG. 8B is a graph showing a signal-to-noise ratio according to an angle between an extension direction of a fake fingerprint and a transmission axis of a polarization layer.

FIG. 8C is a diagram showing a fake fingerprint image perpendicular to a transmission axis of a polarization layer, according to some embodiments of the present disclosure.

FIG. 8D is a drawing showing a fake fingerprint image parallel to a transmission axis of a polarization layer, according to some embodiments of the present disclosure.

FIGS. 9A to 9C are plan views showing shapes of a light receiving element and a first transmission hole, according to some embodiments of the present disclosure.

FIGS. 10A to 10C are plan views showing shapes of a light receiving element and a first transmission hole, according to some embodiments of the present disclosure.

FIG. 11 is a block diagram of an electronic device according to some embodiments.

FIG. 12 illustrates schematic views of electronic devices according to some embodiments.

### DETAILED DESCRIPTION

In the specification, the expression that a first component (or region, layer, part, portion, etc.) is “on”, “connected with”, or “coupled with” a second component means that the first component is directly on, connected with, or coupled with the second component or means that a third component is interposed therebetween.

The same reference numerals refer to the same components. Also, in drawings, the thickness, ratio, and dimension of components are exaggerated for effectiveness of description of technical contents. The term “and/or” includes one or more combinations in each of which associated elements are defined.

Although the terms “first”, “second”, etc. may be used to describe various components, the components should not be construed as being limited by the terms. The terms are only used to distinguish one component from another component. For example, without departing from the scope and spirit of the present disclosure, a first component may be referred to as a second component, and similarly, the second component may be referred to as the first component. The articles “a,” “an,” and “the” are singular in that they have a single referent, but the use of the singular form in the specification should not preclude the presence of more than one referent.

Also, the terms “under”, “below”, “on”, “above”, etc. are used to describe the correlation of components illustrated in drawings. The terms that are relative in concept are described based on a direction shown in drawings.

It will be understood that the terms “include”, “comprise”, “have”, etc. specify the presence of features, numbers, steps, operations, elements, or components, described in the specification, or a combination thereof, not precluding the presence or additional possibility of one or more other features, numbers, steps, operations, elements, or components or a combination thereof.

Unless otherwise defined, all terms (including technical terms and scientific terms) used in the specification have the same meaning as commonly understood by one skilled in the art to which the present disclosure belongs. Furthermore, terms such as terms defined in the dictionaries commonly used should be interpreted as having a meaning consistent with the meaning in the context of the related technology, and should not be interpreted in ideal or overly formal meanings unless explicitly defined herein.

Hereinafter, embodiments of the present disclosure will be described with reference to accompanying drawings.

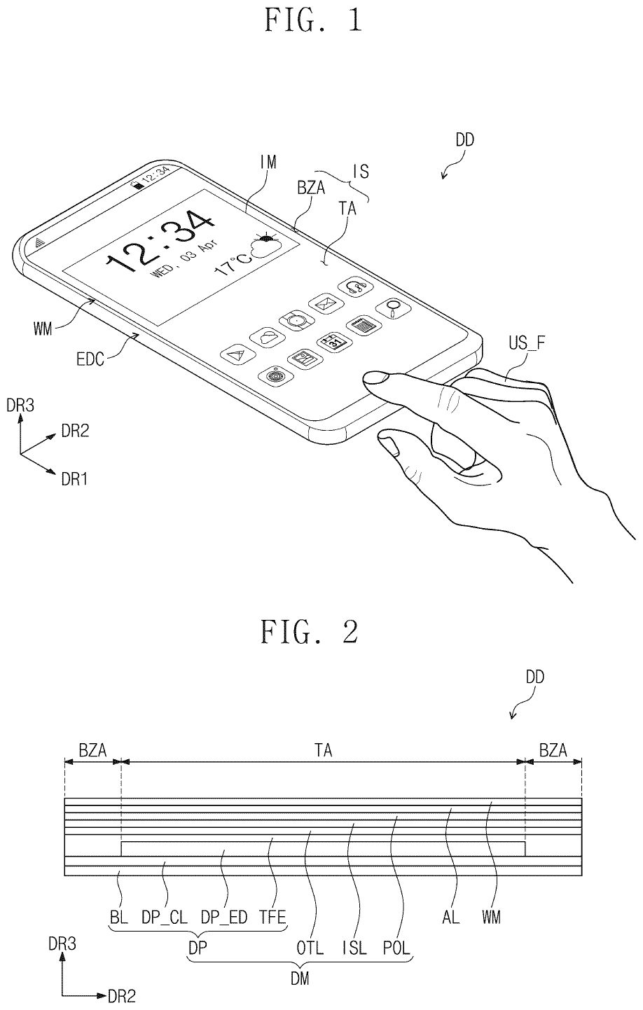

FIG. 1 is a perspective view of a display device, according to some embodiments of the present disclosure. FIG. 2 is a cross-sectional view of a display device, according to some embodiments of the present disclosure.

Referring to FIGS. 1 and 2, a display device DD according to some embodiments of the present disclosure may have a shape of a rectangle having a short side parallel to a first direction DR1 and a long side parallel to a second direction DR2 intersecting the first direction DR1. However, embodiments according to the present disclosure are not limited thereto. For example, the display device DD may have various shapes such as a circle and a polygon.

The display device DD may be a device activated depending on an electrical signal. The display device DD may include various embodiments. For example, the display device DD may be applied to an electronic device such as a smart watch, a tablet PC, a notebook computer, a computer, a smart television, or the like.

Hereinafter, a normal direction perpendicular to a plane defined by the first direction DR1 and the second direction DR2 is defined as a third direction DR3. In the specification, the meaning of “when viewed from above a plane” may mean “when viewed in the third direction DR3”.

A top surface of the display device DD may be defined as a display surface IS, and may be parallel to a plane defined by the first direction DR1 and the second direction DR2. Images IM generated by the display device DD may be provided to a user through the display surface IS.

The display surface IS may be divided into a transmission area TA and a bezel area BZA. The transmission area TA may be an area in which the images IM are displayed. The user visually perceives the images IM through the transmission area TA. According to some embodiments, the transmission area TA is illustrated in the shape of a quadrangle whose corners are rounded. However, this is illustrated as an example. The transmission area TA may have various shapes, and embodiments according to the present disclosure are not limited to the illustrated shape, and may include, for example, a circular shape, an oval shape, a quadrangle with square corners, a polygon, an irregular shape, and the like.

The bezel area BZA is adjacent to the transmission area TA. The bezel area BZA may have a color (e.g., a set or predetermined color). The bezel area BZA may surround the transmission area TA. Accordingly, the shape of the transmission area TA may be defined by the bezel area BZA. However, this is illustrated as an example. For example, the bezel area BZA may be located adjacent to only one side of the transmission area TA or may be omitted.

The display device DD may sense an external input applied from the outside. The external input may include various types of inputs that are provided from the outside of the display device DD. For example, as well as a contact by a part of a body such as the user's hand US_F or a contact by a separate device (e.g., an active pen or a digitizer), the external input may include an external input (e.g., hovering) applied when the user's hand US_F approaches the display device DD or is adjacent to the display device DD within a distance (e.g., a set or predetermined distance). In addition, the external input may have various types such as force, pressure, temperature, light, and the like.

The display device DD may detect the user's biometric information applied from the outside. A biometric information sensing area capable of detecting the user's biometric information may be provided to the display surface IS of the display device DD. The biometric information sensing area may be provided in the entire area of the transmission area TA or may be provided in a partial area of the transmission area TA. As an example of the present disclosure, FIG. 1 illustrates that the entire transmission area TA is utilized as the biometric information sensing area.

The display device DD may include a window WM, a display module DM, and housing EDC. According to some embodiments, an appearance of the display device DD may be implemented by coupling the window WM and the housing EDC.

A front surface of the window WM defines the display surface IS of the display device DD. The window WM may include an optically transparent insulating material. For example, the window WM may include glass or plastic. The window WM may include a multi-layer structure or a single layer structure. For example, the window WM may include a plurality of plastic films bonded to each other by an adhesive or may have a glass substrate and a plastic film bonded to each other by an adhesive.

The display module DM may include a display panel DP, an optical layer OTL, an input sensing layer ISL, and a polarization layer POL. The display panel DP may display an image in response to an electrical signal. The input sensing layer ISL may sense an external input applied from the outside. The external input may be provided in various forms.

The display panel DP according to some embodiments of the present disclosure may be a light emitting display panel, and is not particularly limited thereto. For example, the display panel DP may be an organic light emitting display panel, an inorganic light emitting display panel, or a quantum dot light emitting display panel. A light emitting layer of the organic light emitting display panel may include an organic luminescent material. A light emitting layer of the inorganic light emitting display panel may include an inorganic luminescent material. A light emitting layer of the quantum dot light emitting display panel may include a quantum dot, a quantum rod, and the like. Hereinafter, it is described that the display panel DP is an organic light emitting display panel.

Referring to FIG. 2, the display panel DP includes a base layer BL, a circuit layer DP_CL, an element layer DP_ED, and an encapsulation layer TFE. The display panel DP according to some embodiments of the present disclosure may be a flexible display panel. However, the present disclosure is not limited thereto. For example, the display panel DP may be a foldable display panel, which is folded with respect to a folding axis, or a rigid display panel.

The base layer BL may include a synthetic resin layer. The synthetic resin layer may be a polyimide-based resin layer, and the material thereof is not particularly limited thereto. Besides, the base layer BL may include a glass substrate, a metal substrate, an organic/inorganic composite substrate, or the like.

The circuit layer DP_CL is located on the base layer BL. The circuit layer DP_CL is interposed between the base layer BL and the element layer DP_ED. The circuit layer DP_CL includes at least one insulating layer and a circuit element. Hereinafter, the insulating layer included in the circuit layer DP_CL is referred to as an “intermediate insulating layer”. The intermediate insulating layer includes at least one intermediate inorganic film and at least one intermediate organic film. The circuit element may include a pixel driving circuit, which is included in each of a plurality of pixels for displaying an image, and a sensor driving circuit, which is included in each of a plurality of sensors for recognizing external information. The external information may be biometric information. As an example of the present disclosure, the sensor may be a fingerprint recognition sensor, a proximity sensor, an iris recognition sensor, a blood pressure measurement sensor, or an illuminance sensor. Furthermore, the sensor may be an optical sensor that recognizes the biometric information in an optical scheme. The circuit layer DP_CL may further include signal lines connected to the pixel driving circuit and/or the sensor driving circuit.

The element layer DP_ED may include a light emitting element included in each of the pixels and a light receiving element included in each of the sensors. As an example of the present disclosure, the light receiving element may be a photodiode. The light receiving element may be a sensor that detects or responds to light reflected by a user's fingerprint.

The encapsulation layer TFE encapsulates the element layer DP_ED. The encapsulation layer TFE may include at least one organic film and at least one inorganic film. The inorganic film may include inorganic materials and may protect the element layer DP_ED from moisture/oxygen. The inorganic film may include, but is not particularly limited to, a silicon nitride layer, a silicon oxynitride layer, a silicon oxide layer, a titanium oxide layer, or an aluminum oxide layer. The organic film may include organic materials and may protect the element layer DP_ED from foreign objects such as dust particles.

The optical layer OTL may be formed on the display panel DP. The optical layer OTL may form an optical system for delivering light to a light receiving element. According to some embodiments of the present disclosure, the optical layer OTL may be formed on the display panel DP by a sequential process. In other words, when the optical layer OTL is directly located on the encapsulation layer TFE of the display panel DP, a separate adhesive film is not interposed between the optical layer OTL and the encapsulation layer TFE.

The input sensing layer ISL may be formed on the optical layer OTL. The input sensing layer ISL may be directly located on the optical layer OTL. According to some embodiments of the present disclosure, the input sensing layer ISL may be formed on the optical layer OTL by a sequential process. In other words, when the input sensing layer ISL is directly located on the optical layer OTL, a separate adhesive film is not interposed between the input sensing layer ISL and the optical layer OTL. Alternatively, the adhesive film may be interposed between the input sensing layer ISL and the optical layer OTL. In this case, the input sensing layer ISL may be manufactured through a process separate from the display panel DP and the optical layer OTL and may then be fixed on an upper surface of the display panel DP by the adhesive film.

The input sensing layer ISL may sense an external input (e.g., a user's touch), may change the sensed input into an input signal (e.g., a set or predetermined input signal), and may provide the input signal to the display panel DP. The input sensing layer ISL may include a plurality of sensing electrodes for sensing an external input. The sensing electrodes may sense the external input in a capacitive scheme. The display panel DP may receive an input signal from the input sensing layer ISL and may generate an image corresponding to the input signal.

The location of the optical layer OTL is not limited to the embodiments illustrated in FIG. 2. For example, the optical layer OTL may be located on the input sensing layer ISL. In this case, the input sensing layer ISL may be directly located on the encapsulation layer TFE, and the optical layer OTL may be directly located on the input sensing layer ISL.

The display module DM may further include the polarization layer POL. As an example of the present disclosure, the polarization layer POL may be located on the input sensing layer ISL. However, the present disclosure is not limited thereto. When the optical layer OTL is located on the input sensing layer ISL, the polarization layer POL may be located on the optical layer OTL. The optical layer OTL may include a black matrix provided with a transmission hole.

The polarization layer POL may include a transmission axis and an absorption axis orthogonal to the transmission axis. Accordingly, the polarization layer POL may transmit light components vibrating in a direction parallel to the transmission axis and may absorb light components vibrating in a direction parallel to the absorption axis. As an example of the present disclosure, the transmission axis and the absorption axis of the polarization layer POL may be tilted with respect to the first and second directions DR1 and DR2. For example, the transmission axis may be parallel to a diagonal direction tilted with respect to the first direction DR1 by 45°, and the absorption axis may be parallel to a diagonal direction tilted with respect to the second direction DR2 by 45°.

The display device DD according to some embodiments of the present disclosure may further include an adhesive layer AL. The window WM may be attached to the polarization layer POL by the adhesive layer AL. The adhesive layer AL may include an optical clear adhesive, an optically clear adhesive resin, or a pressure sensitive adhesive (PSA).

The housing EDC is coupled to the window WM. The housing EDC is coupled to the window WM to provide an inner space (e.g., a set or predetermined inner space). The display module DM may be accommodated in the inner space. The housing EDC may include a material having relatively high rigidity. For example, the housing EDC may include glass, plastic, or metal or may include a plurality of frames and/or plates that are composed of a combination thereof. The housing EDC may stably protect configurations of the display device DD accommodated in the inner space from an external impact. Although not illustrated in drawings, a battery module for supplying power required for overall operations of the display device DD may be interposed between the display module DM and the housing EDC.

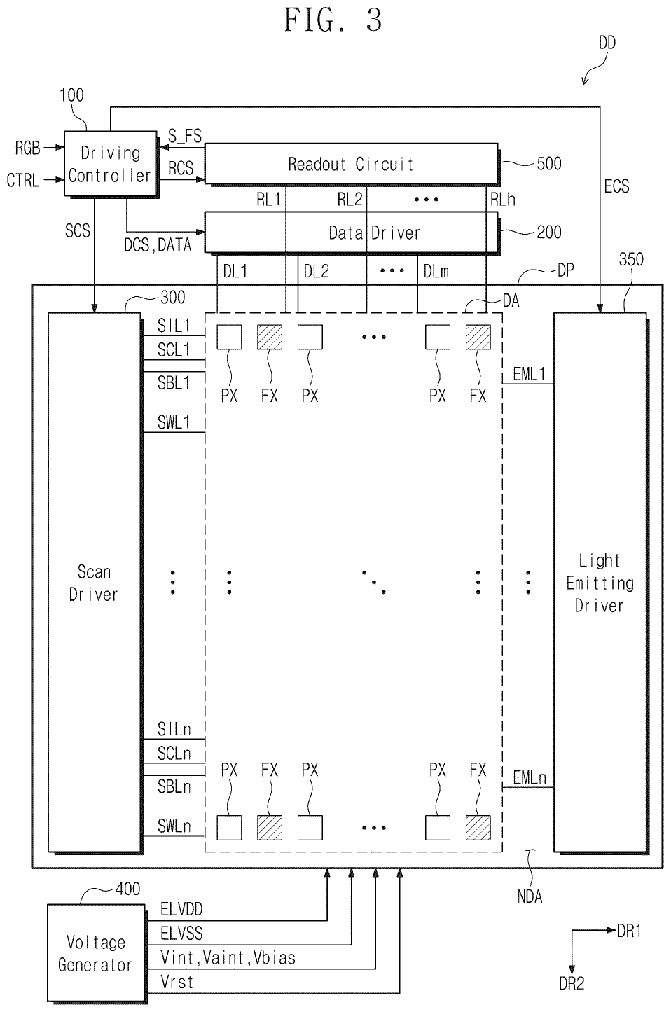

FIG. 3 is a block diagram of a display device, according to some embodiments of the present disclosure.

Referring to FIG. 3, the display device DD includes the display panel DP, a panel driver, and a driving controller 100. As an example of the present disclosure, the panel driver includes a data driver 200, a scan driver 300, a light emitting driver 350, a voltage generator 400, and a readout circuit 500.

The driving controller 100 receives an image signal RGB and a control signal CTRL. The driving controller 100 generates image data DATA by converting a data format of the image signal RGB in compliance with the specification for an interface with the data driver 200. The driving controller 100 outputs a first controller signal SCS, a second controller signal ECS, a third controller signal DCS, and a fourth controller signal RCS.

The data driver 200 receives the third control signal DCS and the image data DATA from the driving controller 100. The data driver 200 converts the image data DATA into data signals and outputs the data signals to a plurality of data lines DL1 to DLm to be described later. The data signals refer to analog voltages corresponding to grayscale values of the image data DATA.

The scan driver 300 receives the first control signal SCS from the driving controller 100. The scan driver 300 may output scan signals to scan lines in response to the first control signal SCS.

The voltage generator 400 generates voltages necessary to operate the display panel DP. According to some embodiments, the voltage generator 400 generates a first driving voltage ELVDD, a second driving voltage ELVSS, a first initialization voltage Vint, a second initialization voltage Vaint, a bias voltage Vbias, and a reset voltage Vrst.

The display panel DP may include a display area DA corresponding to the transmission area TA (as illustrated in FIG. 1) and a non-display area NDA corresponding to the bezel area BZA (as illustrated in FIG. 1).

The display panel DP may include a plurality of pixels PX located in the display area DA and a plurality of sensors FX located in the display area DA. According to some embodiments of the present disclosure, each of the plurality of sensors FX may be interposed between two pixels PX adjacent to each other. The plurality of pixels PX and the plurality of sensors FX may be alternately located on a plane defined in the first and second directions DR1 and DR2. However, the present disclosure is not limited thereto. That is, the two or more pixels PX may be positioned between the two sensors FX adjacent to each other in the first direction DR1 among the plurality of sensors FX. Alternatively, the two or more pixels PX may be positioned between the two sensors FX adjacent to each other in the second direction DR2 among the plurality of sensors FX.

The display panel DP further includes initialization scan lines SIL1 to SILn, compensation scan lines SCL1 to SCLn, write scan lines SWL1 to SWLn, black scan lines SBL1 to SBLn, emission control lines EML1 to EMLn, data lines DL1 and DL2 to DLm, and readout lines RL1 and RL2 to RLh. The initialization scan lines SIL1 to SILn, the compensation scan lines SCL1 to SCLn, the write scan lines SWL1 to SWLn, the black scan lines SBL1 to SBLn, and the emission control lines EML1 to EMLn extend in the first direction DR1. The initialization scan lines SIL1 to SILn, the compensation scan lines SCL1 to SCLn, the write scan lines SWL1 to SWLn, the black scan lines SBL1 to SBLn, and the emission control lines EML1 to EMLn are arranged spaced from one another in the second direction DR2. The data lines DL1 to DLm and the readout lines RL1 to RLh extend in the second direction DR2 and are arranged spaced apart from one another in the first direction DR1. Here, each of ‘n’, ‘m’, and ‘h’ is a natural number of 1 or more.

The plurality of pixels PX are electrically connected to the initialization scan lines SIL1 to SILn, the compensation scan lines SCL1 to SCLn, the write scan lines SWL1 to SWLn, the black scan lines SBL1 to SBLn, the emission control lines EML1 to EMLn, and the data lines DL1 to DLm. For example, each of the plurality of pixels PX may be electrically connected to four scan lines. However, the number of scan lines connected to each of the pixels PX is not limited thereto, and may be changed.

The plurality of sensors FX are electrically connected to the write scan lines SWL1 to SWLn and the readout lines RL1 to RLh. Each of the plurality of sensors FX may be electrically connected to one scan line. However, the present disclosure is not limited thereto. The number of scan lines connected to each of the sensors FX may be changed. As an example of the present disclosure, the number of readout lines RL1 to RLh may be less than or equal to the number of data lines DL1 to DLm. For example, the number of readout lines RL1 to RLh may correspond to ½, ¼, or ⅛ of the number of data lines DL1 to DLm.

The scan driver 300 may be located in the non-display area NDA of the display panel DP. The scan driver 300 receives the first control signal SCS from the driving controller 100. In response to the first control signal SCS, the scan driver 300 outputs initialization scan signals to the initialization scan lines SIL1 to SILn and outputs compensation scan signals to the compensation scan lines SCL1 to SCLn. Furthermore, in response to the first control signal SCS, the scan driver 300 may output write scan signals to the write scan lines SWL1 to SWLn and may output black scan signals to the black scan lines SBL1 to SBLn. Alternatively, the scan driver 300 may include a first scan driver and a second scan driver. The first scan driver may output the initialization scan signals and the compensation scan signals. The second scan driver may output the write scan signals and the black scan signals.

The light emitting driver 350 may be located in the non-display area NDA of the display panel DP. The light emitting driver 350 receives the second control signal ECS from the driving controller 100. The light emitting driver 350 may output emission control signals to the emission control lines EML1 to EMLn in response to the second control signal ECS. Alternatively, the scan driver 300 may be connected to the emission control lines EML1 to EMLn. In this case, the light emitting driver 350 may be omitted, and the scan driver 300 may output the emission control signals to the emission control lines EML1 to EMLn.

The readout circuit 500 receives the fourth control signal RCS from the driving controller 100. The readout circuit 500 may receive detection signals from the readout lines RL1 to RLh in response to the fourth control signal RCS. The readout circuit 500 may process the detection signals received from the readout lines RL1 to RLh and may provide a processed detection signals S_FS to the driving controller 100. The driving controller 100 may recognize biometric information based on the detection signals S_FS.

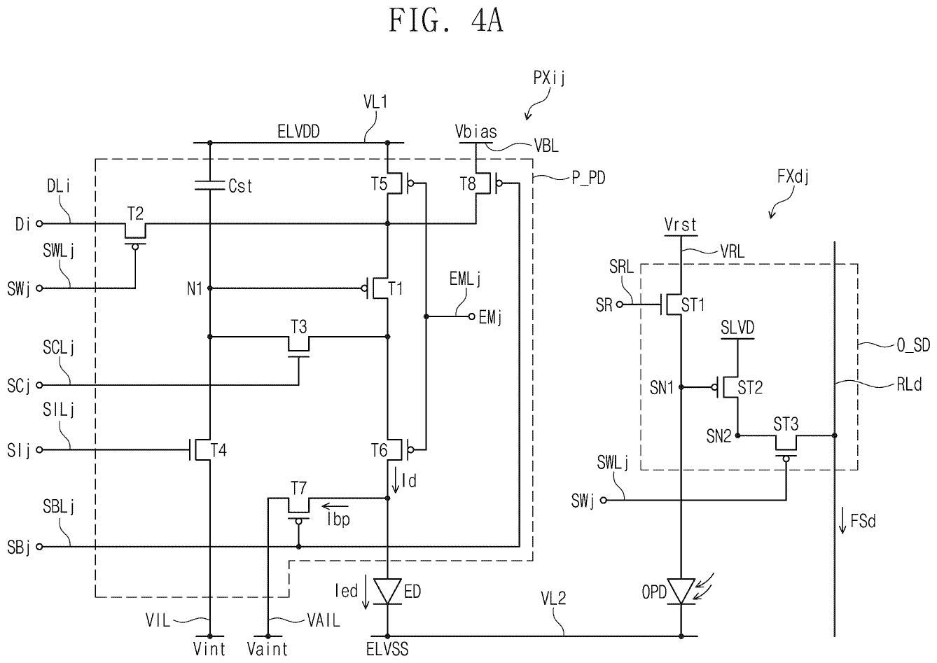

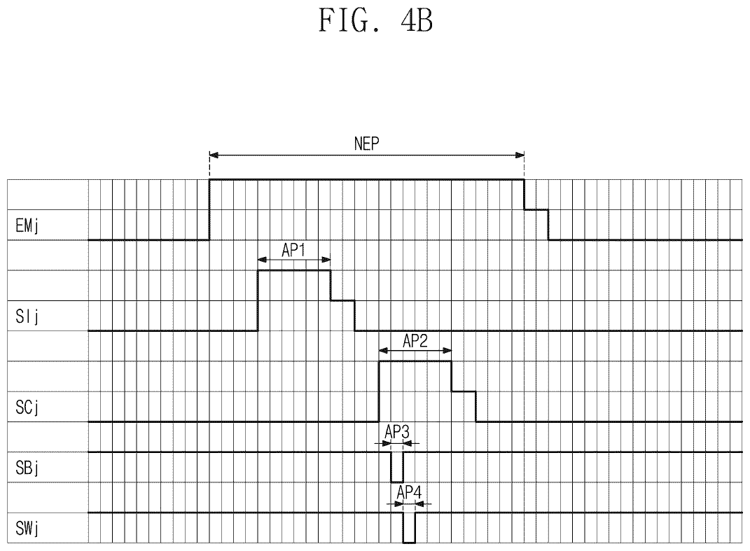

FIG. 4A is a circuit diagram illustrating a pixel and a sensor, according to some embodiments of the present disclosure. Although FIG. 4A illustrates various components in a pixel and a sensor according to some embodiments, embodiments according to the present disclosure are not limited thereto, and according to various embodiments, the pixel and the sensor may include additional components or fewer components without departing from the spirit and scope of embodiments according to the present disclosure.

FIG. 4B is a waveform diagram for describing operations of the pixel and the sensor shown in FIG. 4A.

FIG. 4A illustrates an equivalent circuit diagram of a single pixel PXij among the pixels PX illustrated in FIG. 3. Because each of the plurality of pixels PX has the same circuit structure, a detailed description of the remaining pixels will be replaced with a description of a circuit structure of the pixel PXij. Moreover, FIG. 4A shows an equivalent circuit diagram of one sensor FXdj among the plurality of sensors FX shown in FIG. 3. Because each of the plurality of sensors FX has the same circuit structure, the detailed description of the remaining sensors will be replaced with a description of a circuit structure for the sensor FXdj.

Referring to FIG. 4A, the pixel PXij is connected with the i-th data line DLi of the data lines DL1 to DLm, the j-th initialization scan line SILj of the initialization scan lines SIL1 to SILn, the j-th compensation scan line SCLj of the compensation scan lines SCL1 to SCLn, the j-th write scan line SWLj of the write scan lines SWL1 to SWLn, the j-th black scan line SBLj of the black scan lines SBL1 to SBLn, and the j-th emission control line EMLj of the emission control lines EML1 to EMLn.

The pixel PXij includes a light emitting element ED and a pixel driving circuit P_PD. The light emitting element ED may be a light emitting diode. As an example of the present disclosure, the light emitting element ED may be an organic light emitting diode including an organic light emitting layer.

The pixel driving circuit P_PD includes first to eighth transistors T1, T2, T3, T4, T5, T6, T7, and T8 and one capacitor Cst. At least one of the first to eighth transistors T1 to T8 may be a transistor having a low-temperature polycrystalline silicon (LTPS) semiconductor layer. Some of the first to eighth transistors T1 to T8 may be P-type transistors, and the other(s) thereof may be N-type transistors. At least one of the first to eighth transistors T1 to T8 may be a transistor having an oxide semiconductor layer. For example, the third and fourth transistors T3 and T4 may be oxide semiconductor transistors, and the first, second, and fifth to eighth transistors T1, T2, and T5 to T8 may be LTPS transistors. The third and fourth transistors T3 and T4 may be NMOS transistors.

A configuration of the pixel driving circuit P_PD according to the present disclosure is not limited to the embodiments illustrated in FIG. 4A. The pixel driving circuit P_PD illustrated in FIG. 4A is only an example. For example, the configuration of the pixel driving circuit P_PD may be modified and implemented. For example, all of the first, second, and fifth to eighth transistors T1, T2, and T5 to T8 may be P-type transistors or N-type transistors.

The j-th initialization scan line SILj, the j-th compensation scan line SCLj, the j-th write scan line SWLj, the j-th black scan line SBLj, and the j-th emission control line EMLj may transfer a j-th initialization scan signal Slj, a j-th compensation scan signal SCj, a j-th write scan signal SWj, a j-th black scan signal SBj, and a j-th emission control signal EMj to the pixel PXij, respectively. The i-th data line DLi transfers an i-th data signal Di to the pixel PXij. The i-th data signal Di may have a voltage level corresponding to the image signal RGB (see FIG. 3) input to the display device DD (see FIG. 3).

As an example of the present disclosure, the pixel PXij may be connected to first and second driving voltage lines VL1 and VL2, first and second initialization voltage lines VIL and VAIL, and a bias voltage line VBL. The first driving voltage line VL1 may deliver the first driving voltage ELVDD to the pixel PXij. The second driving voltage line VL2 may deliver the second driving voltage ELVSS to the pixel PXij. Moreover, the first initialization voltage line VIL may deliver the first initialization voltage Vint to the pixel PXij. The second initialization voltage line VAIL may deliver the second initialization voltage Vaint to the pixel PXij. The bias voltage line VBL may deliver the bias voltage Vbias to the pixel PXij.

The first transistor T1 is connected between the first driving voltage line VL1 receiving the first driving voltage ELVDD and the light emitting element ED. The first transistor T1 includes a first electrode connected to the first driving voltage line VL1 via the fifth transistor T5, a second electrode connected to an anode electrode of the light emitting element ED via the sixth transistor T6, and a third electrode (e.g., a gate electrode) connected to one end (e.g., a first node N1) of the capacitor Cst. The first transistor T1 may receive the data signal Di transferred through the i-th data line DLi depending on a switching operation of the second transistor T2 and then may supply a driving current Id to the light emitting element ED.

The second transistor T2 is connected between the i-th data line DLi and the first electrode of the first transistor T1. The second transistor T2 includes a first electrode connected with the i-th data line DLi, a second electrode connected with the first electrode of the first transistor T1, and a third electrode (e.g., a gate electrode) connected with the j-th write scan line SWLj. The second transistor T2 may be turned on in response to the j-th write scan signal SWj transferred through the j-th write scan line SWLj and then may transfer the i-th data signal Di transferred from the i-th data line DLi to the first electrode of the first transistor T1.

The third transistor T3 is connected between the second electrode of the first transistor T1 and the first node N1. The third transistor T3 includes a first electrode connected with the third electrode of the first transistor T1, a second electrode connected with the second electrode of the first transistor T1, and a third electrode (e.g., a gate electrode) connected with the j-th compensation scan line SCLj. The third transistor T3 may be turned on in response to the j-th compensation scan signal SCj transferred through the j-th compensation scan line SCLj and may connect the third electrode and the second electrode of the first transistor T1. In this case, the first transistor T1 may be diode-connected.

The fourth transistor T4 is connected between the first node N1 and the first initialization voltage line VIL through which the first initialization voltage Vint is applied. The fourth transistor T4 includes a first electrode connected to the first initialization voltage line VIL through which the first initialization voltage Vint is supplied, a second electrode connected to the first node N1, and a third electrode (e.g., a gate electrode) connected to the j-th initialization scan line SILj. The fourth transistor T4 is turned on in response to the j-th initialization scan signal Slj received through the j-th initialization scan line SILj. The fourth transistor T4 thus turned on may transfer the first initialization voltage Vint to the first node N1 such that a potential of the third electrode of the first transistor T1 (i.e., a potential of the first node N1) is initialized.

The fifth transistor T5 includes a first electrode connected with the first driving voltage line VL1, a second electrode connected with the first electrode of the first transistor T1, and a third electrode (e.g., a gate electrode) connected with the j-th emission control line EMLj.

The sixth transistor T6 includes a first electrode connected to the second electrode of the first transistor T1, a second electrode connected to the anode electrode of the light emitting element ED, and a third electrode (e.g., a gate electrode) connected to the j-th emission control line EMLj.

The fifth and sixth transistors T5 and T6 are simultaneously turned on in response to the j-th emission control signal EMj transferred through the j-th emission control line EMLj. The first driving voltage ELVDD applied through the fifth transistor T5 thus turned on may be compensated through the diode-connected first transistor T1 and then may be delivered to the light emitting element ED.

The seventh transistor T7 includes a first electrode connected to the second initialization voltage line VAIL through which the second initialization voltage Vaint is supplied, a second electrode connected to the second electrode of the sixth transistor T6, and a third electrode (e.g., a gate electrode) connected to the j-th black scan line SBLj. A voltage level of the second initialization voltage Vaint may lower than or equal to that of the first initialization voltage Vint.

The eighth transistor T8 includes a first electrode connected to the bias voltage line VBL through which the bias voltage Vbias is supplied, a second electrode connected to the first electrode of the first transistor T1, and a third electrode (e.g., a gate electrode) connected to the j-th black scan line SBLj.

The seventh and eighth transistors T7 and T8 are turned on simultaneously in response to the j-th black scan signal SBj received through the j-th black scan line SBLj. The second initialization voltage Vaint applied through the turned-on seventh transistor T7 may be delivered to the anode electrode of the light emitting element ED. Accordingly, the anode electrode of the light emitting element ED may be initialized with the second initialization voltage Vaint. The bias voltage Vbias applied through the eighth transistor T8 thus turned on may be delivered to the first electrode of the first transistor T1. Therefore, the bias voltage Vbias may be periodically applied to the first electrode of the first transistor T1. As a result, it is possible to prevent issues such as deterioration of display quality that occurs when the potential difference between the first and second electrodes of the first transistor T1 increases to be greater than or equal to a specific level due to magnetic hysteresis.

As described above, one end of the capacitor Cst is connected with the third electrode of the first transistor T1, and the other end of the capacitor Cst is connected with the first driving voltage line VL1. A cathode electrode of the light emitting element ED may be connected with the second driving voltage line VL2 that transfers the second driving voltage ELVSS. A voltage level of the second driving voltage ELVSS may be lower than a voltage level of the first driving voltage ELVDD. As an example of the present disclosure, the voltage level of the second driving voltage ELVSS may be lower than the voltage level of each of the first and second initialization voltages Vint and Vaint.

Referring to FIGS. 4A and 4B, the j-th emission control signal EMj has a high level during a non-emission period NEP. During the non-emission period NEP, the j-th initialization scan signal Slj is activated. During an activation period AP1 (hereinafter, referred to as a “first activation period”) of the j-th initialization scan signal Slj, when the j-th initialization scan signal Slj of a high level is provided through the j-th initialization scan line SILj, the fourth transistor T4 is turned on in response to the j-th initialization scan signal Slj of the high level. The first initialization voltage Vint is transferred to the third electrode of the first transistor T1 via the fourth transistor T4 thus turned on, and the first node N1 is initialized with the first initialization voltage Vint. Accordingly, the first activation period AP1 may be defined as an initialization period of the pixel PXij.

Next, the j-th compensation scan signal SCj is activated, and the third transistor T3 is turned on when the j-th compensation scan signal SCj of the high level is supplied through the j-th compensation scan line SCLj during an activation period AP2 (hereinafter, referred to as a “second activation period”) of the j-th compensation scan signal SCj. The first transistor T1 is diode-connected by the third transistor T3 thus turned on to be forward-biased. The first activation period AP1 may not overlap the second activation period AP2.

The j-th write scan signal SWj is activated within the second activation period AP2. The j-th write scan signal SWj has a low level during an activation period AP4 (hereinafter, referred to as a “fourth activation period”). During the fourth activation period AP4, the second transistor T2 is turned on in response to the j-th write scan signal SWj of the low level. In this case, a compensation voltage “Di-Vth” is applied to the third electrode of the first transistor T1. Here, the compensation voltage “Di-Vth” may correspond to a result of subtracting a threshold voltage Vth of the first transistor T1 from a voltage of the i-th data signal Di supplied from the i-th data line DLi. That is, a potential of the third electrode of the first transistor T1 may be the compensation voltage “Di-Vth”. The fourth activation period AP4 may overlap the second activation period AP2. The duration of the second activation period AP2 may be greater than the duration of the fourth activation period AP4.

The first driving voltage ELVDD and the compensation voltage “Di-Vth” may be respectively applied to opposite ends of the capacitor Cst, and charges corresponding to a voltage difference between the opposite ends of the capacitor Cst may be stored in the capacitor Cst. Herein, a high level period of the j-th compensation scan signal SCj may be referred to as a “compensation period” of the pixel PXij.

In the meantime, the j-th black scan signal SBj is activated within the second activation period AP2 of the j-th compensation scan signal SCj. The j-th black scan signal SBj has a low level during an activation period AP3 (hereinafter, referred to as a “third activation period”). During the third activation period AP3, the seventh transistor T7 is turned on by receiving the j-th black scan signal SBj of a low level through the j-th black scan line SBLj. A part of the driving current Id may be drained through the seventh transistor T7 as a bypass current lbp. The third activation period AP3 may overlap the second activation period AP2. The duration of the second activation period AP2 may be greater than the duration of the third activation period AP3. The third activation period AP3 may precede the fourth activation period AP4, and may not overlap the fourth activation period AP4.

In the case where the pixel PXij displays a black image, when the light emitting element ED emits light even though the minimum driving current of the first transistor T1 flows as the driving current Id, the pixel PXij may not normally display a black image. Accordingly, the seventh transistor T7 in the pixel PXij according to some embodiments of the present disclosure may drain (or disperse) a part of the minimum driving current of the first transistor T1 to a current path, which is different from a current path to the light emitting element ED, as the bypass current lbp. Here, the minimum driving current of the first transistor T1 means the current flowing into the first transistor T1 under the condition that the first transistor T1 is turned off because a gate-source voltage Vgs of the first transistor T1 is less than the threshold voltage Vth. As the minimum driving current (e.g., a current of 10 pA or less) flowing to the first transistor T1 is transferred to the light emitting element ED under the condition that the first transistor T1 is turned off, an image of a black gray scale is displayed. When the pixel PXij displays a black image, the bypass current lbp has a relatively large influence on the minimum driving current. On the other hand, when the pixel PXij displays an image such as a normal image or a white image, the bypass current lbp has little effect on the driving current Id. Accordingly, when a black image is displayed, a current (i.e., a light emitting current led) that corresponds to a result of subtracting the bypass current lbp flowing through the seventh transistor T7 from the driving current Id is provided to the light emitting element ED, and thus a black image may be clearly displayed. Accordingly, the pixel PXij may implement an accurate black grayscale image by using the seventh transistor T7, and thus a contrast ratio may be relatively improved.

Next, the j-th emission control signal EMj that is supplied from the j-th emission control line EMLj transitions from the high level to the low level. The fifth transistor T5 and the sixth transistor T6 are turned on by the emission control signal EMj having a low level. In this case, because a difference is present between the voltage of the third electrode of the first transistor T1 and the first driving voltage ELVDD, the driving current Id is generated. The driving current Id thus generated is supplied to the light emitting element ED through the sixth transistor T6, and thus, the current led flows through the light emitting element ED.

Returning to FIG. 4A, the sensor FXdj is connected to the d-th readout line RLd among the readout lines RL1 to RLh, the j-th write scan line SWLj, and a reset control line SRL.

The sensor FXdj includes a light receiving element OPD and a sensor driving circuit O_SD. As an example of the present disclosure, the light receiving element OPD may be an organic photodiode including an organic material as a photoelectric conversion layer. FIG. 4A illustrates a structure in which the sensor FXdj includes one light receiving element, but the present disclosure is not limited thereto. For example, the sensor FXdj may include the plurality of light receiving elements OPD connected in parallel to each other.

An anode electrode of the light receiving element OPD may be connected to a first sensing node SN1. A cathode electrode of the light receiving element OPD may be connected to the second driving voltage line VL2 that delivers the second driving voltage ELVSS. The cathode electrode of the light receiving element OPD may be electrically connected to the cathode electrode of the light emitting element ED. As an example of the present disclosure, the cathode electrode of the light receiving element OPD may be integrated with the cathode electrode of the light emitting element ED to form a common cathode electrode.

The sensor driving circuit O_SD includes three transistors ST1 to ST3. The three transistors ST1 to ST3 may include the reset transistor ST1, the amplification transistor ST2, and the output transistor ST3. At least one of the reset transistor ST1, the amplification transistor ST2, or the output transistor ST3 may be an oxide semiconductor transistor. As an example of the present disclosure, the reset transistor ST1 may be an oxide semiconductor transistor, and the amplification transistor ST2 and the output transistor ST3 may be LTPS transistors. However, the present disclosure is not limited thereto. The reset transistor ST1 and the output transistor ST3 may be oxide semiconductor transistors, and the amplification transistor ST2 may be an LTPS transistor.

Also, some of the reset transistor ST1, the amplification transistor ST2, and the output transistor ST3 may be P-type transistors, and the other(s) thereof may be an N-type transistor. As an example of the present disclosure, the amplification transistor ST2 and the output transistor ST3 may be PMOS transistors, and the reset transistor ST1 may be an NMOS transistor. However, the present disclosure is not limited thereto. For example, all the transistors ST1, ST2, and ST3 may be N-type transistors or P-type transistors.

A part (e.g., the reset transistor ST1) of the reset transistor ST1, the amplification transistor ST2, and the output transistor ST3 may be a transistor having the same type as each of the third and fourth transistors T3 and T4 of the pixel PXij. A type of the amplification transistor ST2 and the output transistor ST3 may be the same as that of the first, second, and fifth to eighth transistors T1, T2, and T5 to T8 of the pixel PXij.

The circuit configuration of the sensor driving circuit O_SD according to the present disclosure is not limited to that illustrated in FIG. 4A. The sensor driving circuit O_SD illustrated in FIG. 4A is only an example, and the configuration of the sensor driving circuit O_SD may be modified and implemented.

The reset transistor ST1 includes a first electrode receiving the reset voltage Vrst, a second electrode connected to the first sensing node SN1, and a third electrode receiving a reset control signal SR. The reset transistor ST1 may reset a potential of the first sensing node SN1 to the reset voltage Vrst in response to the reset control signal SR. The reset control signal SR may be a signal provided through the reset control line SRL. However, the present disclosure is not limited thereto. Alternatively, the reset control signal SR may be the j-th compensation scan signal SCj supplied through the j-th compensation scan line SCLj. That is, the reset transistor ST1 may receive the j-th compensation scan signal SCj, which is supplied through the j-th compensation scan line SCLj, as the reset control signal SR. As an example of the present disclosure, during the activation period of the reset control signal SR, the reset voltage VRST may have a voltage level lower than the second driving voltage ELVSS. The reset voltage Vrst may be delivered to the sensor FXdj through a reset voltage line VRL. The reset voltage Vrst may be a DC voltage maintained at a voltage level lower than the second driving voltage ELVSS.

The reset transistor ST1 may include a plurality of sub-reset transistors connected to one another in series. For example, the reset transistor ST1 may include two sub-reset transistors (hereinafter referred to as “first and second sub-reset transistors”). In this case, a third electrode of the first sub-reset transistor and a third electrode of the second sub-reset transistor are connected with the reset control line SRL. Also, a second electrode of the first sub-reset transistor and a first electrode of the second sub-reset transistor may be electrically connected with each other. Also, the reset voltage Vrst may be applied to a first electrode of the first sub-reset transistor, and a second electrode of the second sub-reset transistor may be electrically connected with the first sensing node SN1. However, the number of sub-reset transistors is not limited thereto and may be variously changed or modified.

The amplification transistor ST2 includes a first electrode receiving a sensing driving voltage SLVD, a second electrode connected with a second sensing node SN2, and a third electrode connected with the first sensing node SN1. The amplification transistor ST2 is turned on in response to the potential of the first sensing node SN1 to apply the sensing driving voltage SLVD to the second sensing node SN2. As an example of the present disclosure, the sensing driving voltage SLVD may correspond to one of the first driving voltage ELVDD, the first initialization voltage Vint, and the second initialization voltage Vaint. When the sensing driving voltage SLVD is the first driving voltage ELVDD, the first electrode of the amplification transistor ST2 may be electrically connected with the first driving voltage line VL1. When the sensing driving voltage SLVD is the first initialization voltage Vint, the first electrode of the amplification transistor ST2 may be electrically connected with the first initialization voltage line VIL. When the sensing driving voltage SLVD is the second initialization voltage Vaint, the first electrode of the amplification transistor ST2 may be electrically connected with the second initialization voltage line VAIL.

The output transistor ST3 includes a first electrode connected to the second sensing node SN2, a second electrode connected to the d-th readout line RLd, and a third electrode receiving an output control signal. The output transistor ST3 may deliver a sensing signal FSd to the d-th readout line RLd in response to the output control signal. The output control signal may be the j-th write scan signal SWj supplied through the j-th write scan line SWLj. That is, the output transistor ST3 may receive the j-th write scan signal SWj supplied from the j-th write scan line SWLj as the output control signal.

The light receiving element OPD of the sensor FXdj may be exposed to light during the emission period of the light emitting element ED. The light may be output from the light emitting element ED.

When the hand US_F of a user (see FIG. 1) touches the display surface IS (see FIG. 1), the light receiving element OPD generates photocharges corresponding to light reflected by a ridge or valley between ridges of a fingerprint. The amount of current flowing through the light receiving element OPD is changed by the generated photocharges. When the light receiving element OPD receives the light reflected by the ridge of the fingerprint, the current flowing through the light receiving element OPD may be referred to as a “first current”. When the light receiving element OPD receives the light reflected by the valley of the fingerprint, the current flowing through the light receiving element OPD may be referred to as a “second current”. Because there is a difference in light intensity between light reflected by the fingerprint's ridge and light reflected by the fingerprint's valley, the difference in light intensity is a difference between the first and second currents. When the first current flows through the light receiving element OPD, a potential of the first sensing node SN1 may be referred to as a “first potential”. When the second current flows through the light receiving element OPD, a potential of the first sensing node SN1 may be referred to as a “second potential”. As an example of the present disclosure, the first current may be greater than the second current. In this case, the first potential may be lower than the second potential.

The amplification transistor ST2 may be a source follower amplifier generating a source-drain current in proportion to the potential of the first sensing node SN1 input to the third electrode of the amplification transistor ST2.

During the fourth activation period AP4, the j-th write scan signal SWj of a low level is supplied to the output transistor ST3 through the j-th write scan line SWLj. When the output transistor ST3 is turned on in response to the j-th write scan signal SWj of the low level, the sensing signal FSd corresponding to a current flowing through the amplification transistor ST2 may be output to the d-th readout line RLd.

Next, when the reset control signal SR of a high level is supplied through the reset control line SRL during a reset period, the reset transistor ST1 is turned on. The reset period may be defined as an activation period (i.e., a high-level period) of the reset control signal SR. Alternatively, when the reset transistor ST1 is composed of a P-type transistor, the reset control signal SR of a low level may be supplied to the reset control line SRL during the reset period. During the reset period, a potential of the first sensing node SN1 may be reset to a potential corresponding to the reset voltage Vrst. As an example of the present disclosure, the reset voltage Vrst may have a lower voltage level than the second driving voltage ELVSS.

Next, when the reset period ends, the light receiving element OPD may generate photocharges corresponding to the received light, and the generated photocharges may be accumulated in the first sensing node SN1.

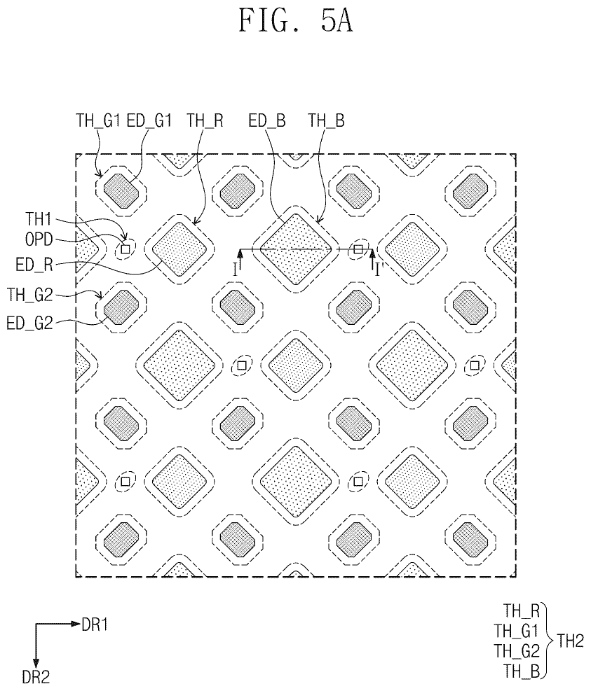

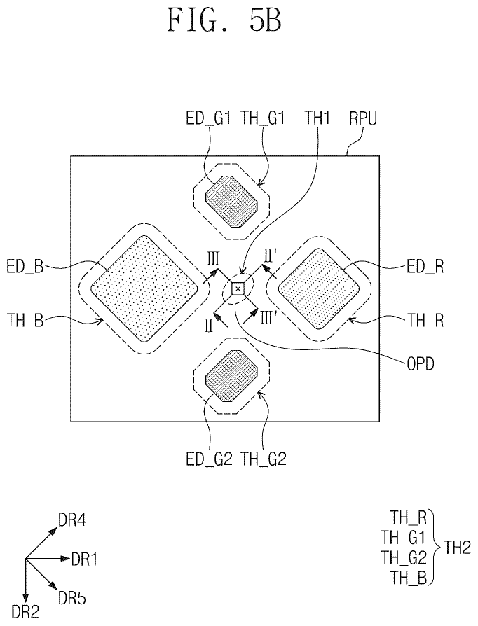

FIG. 5A is a plan view showing an element layer and an optical layer, according to some embodiments of the present disclosure. FIG. 5B is an enlarged view showing a portion of FIG. 5A.

Referring to FIGS. 5A and 5B, the element layer DP_ED (see FIG. 2) includes a plurality of light emitting elements ED_R, ED_G1, ED_G2, and ED_B and a plurality of light receiving elements OPD.

The light emitting elements ED_R, ED_G1, ED_G2, and ED_B may be grouped into a plurality of reference units RPU. As an example of the present disclosure, the respective reference unit RPU may include four light emitting elements (i.e., the first light emitting element ED_R (hereinafter, referred to as a “red light emitting element”), the second light emitting element ED_B (hereinafter, referred to as a “blue light emitting element”), two third light emitting elements ED_G1 and ED_G2 (hereinafter, referred to as “first and second green light emitting elements”). However, the number of light emitting elements included in the respective reference unit RPU is not limited thereto. Alternatively, the respective reference unit RPU may include three light emitting elements (i.e., the red light emitting element ED_R, the blue light emitting element ED_B, and the green light emitting element (one of the first and second green light emitting elements ED_G1 and ED_G2)).

As an example of the present disclosure, the red light emitting element ED_R outputs first color light (e.g., red light), and the blue light emitting element ED_B outputs second color light (e.g., blue light) different from the first color light. Each of the first and second green light emitting elements ED_G1 and ED_G2 outputs third color light (e.g., green light) different from the first color light and the second color light. The green light output from the first green light emitting element ED_G1 may have the same wavelength band as the green light output from the second green light emitting element ED_G2.

In the first and second directions DR1 and DR2, the red light emitting elements ED_R and the blue light emitting elements ED_B may be placed alternately and repeatedly. The first and second green light emitting elements ED_G1 and ED_G2 are alternately and repeatedly placed in the first direction DR1 and alternately and repeatedly placed in the second direction DR2.

As an example of the present disclosure, the red light emitting element ED_R may have a size greater than the first and second green light emitting elements ED_G1 and ED_G2. Moreover, the blue light emitting element ED_B may have a size greater than or equal to the size of the red light emitting element ED_R. The size of each of the light emitting elements ED_R, ED_G1, ED_G2, and ED_B is not limited thereto, and may be variously modified and applied. For example, according to some embodiments of the present disclosure, the light emitting elements ED_R, ED_G1, ED_G2, and ED_B may have the same size as one another.

Each of the red light emitting element ED_R, the blue light emitting element ED_B, the first green light emitting element ED_G1, and the second green light emitting element ED_G2 may have a polygonal shape (e.g., one of shapes of a rhombus, a square, a rectangle, a hexagon, and an octagon), a circular shape, or an elliptical shape. The first and second green light emitting elements ED_G1 and ED_G2 may have different shapes from the red and blue light emitting elements ED_R and ED_B. As an example of the present disclosure, each of the red and blue light emitting elements ED_R and ED_B may have a rhombus shape with rounded corners, and each of the first and second green light emitting elements ED_G1 and ED_G2 may have an octagonal shape. Each of the first and second green light emitting elements ED_G1 and ED_G2 may have an octagonal shape elongating in a specific direction. An extension direction of the first green light emitting element ED_G1 may intersect (or be perpendicular) to an extension direction of the second green light emitting element ED_G2. The extension direction of each of the first and second green light emitting elements ED_G1 and ED_G2 may be an oblique direction (e.g., diagonal direction) with respect to the first and second directions DR1 and DR2.

One of the plurality of light receiving elements OPD may be placed to correspond to the respective reference unit RPU. However, the number of light receiving elements (OPDs) placed to correspond to the respective reference unit RPU is not limited thereto. For example, the two light receiving elements OPD may be placed to correspond to the respective reference unit RPU.

The plurality of light receiving elements OPD are placed in the first and second directions DR1 and DR2. Each of the light receiving elements OPD is placed between the red and blue light emitting elements ED_R and ED_B in the first direction DR1, and is placed between the first and second green light emitting elements ED_G1 and ED_G2 in the second direction DR2.

As an example of the present disclosure, each of the plurality of light receiving elements OPD may have a shape the same as or different from the shape of each of the light emitting elements ED_G1, ED_G2, ED_R, and ED_B. In FIG. 5B, each of the plurality of light receiving elements OPD has a square shape. However, the plurality of light receiving elements OPD may have various shapes, such as different polygonal shapes (e.g., a rhombus, a rectangle, a hexagon, or an octagon), a circular shape, or an elliptical shape, respectively.

Each of the plurality of light receiving elements OPD may have a size smaller than or equal to the first and second green light emitting elements ED_G1 and ED_G2. However, the size of each of the plurality of light receiving elements OPD is not particularly limited thereto and may be applied while being modified in various ways.

The optical layer OTL (see FIG. 2) may be formed on the element layer DP_ED. The optical layer OTL may include a plurality of transmission holes. The plurality of transmission holes includes first transmission holes TH1 formed corresponding to the light receiving elements OPD and second transmission holes TH2 formed corresponding to the light emitting elements ED_G1, ED_G2, ED_R, and ED_B. The second transmission holes TH2 may include a 2-1st transmission hole TH_R corresponding to the red light emitting element ED_R, a 2-2nd transmission hole TH_B corresponding to the blue light emitting element ED_B, a 2-3rd transmission hole TH_G1 corresponding to the first green light emitting element ED_G1, and a 2-4th transmission hole TH_G2 corresponding to the second green light emitting element ED_G2.

The 2-1st transmission hole TH_R may have the same (or corresponding) shape as the red light emitting element ED_R. The 2-2nd transmission hole TH_B may have the same (or corresponding) shape as the blue light emitting element ED_B. The 2-3rd transmission hole TH_G1 may have the same (or corresponding) shape as the first green light emitting element ED_G1. The 2-4th transmission hole TH_G2 may have the same (or corresponding) shape as the second green light emitting element ED_G2. However, the present disclosure is not limited thereto. For example, the 2-1st transmission hole TH_R may have a different shape from the shape of the red light emitting element ED_R. The 2-2nd transmission hole TH_B may have a different shape from the shape of the blue light emitting element ED_B. The 2-3rd transmission hole TH_G1 may have a different shape from the shape of the first green light emitting element ED_G1. The 2-4th transmission hole TH_G2 may have a different shape from the shape of the second green light emitting element ED_G2.

The red light generated from the red light emitting element ED_R is output through the 2-1st transmission hole TH_R. The blue light generated from the blue light emitting element ED_B is output through the 2-2nd transmission hole TH_B. The first green light generated from the first green light emitting element ED_G1 is output through the 2-3rd transmission hole TH_G1. The second green light generated from the second green light emitting element ED_G2 is output through the 2-4th transmission hole TH_G2.

Each of the first transmission holes TH1 may provide a passage through which external light is incident onto the light receiving elements OPD. The first transmission holes TH1 may have shapes the same as or different from shapes of the light receiving elements OPD. As an example of the present disclosure, in FIGS. 5A and 5B, each of the first transmission holes TH1 has a different shape from the shape of the light receiving elements OPD. For example, each of the first transmission holes TH1 may have an elliptical shape. Each of the first transmission holes TH1 may have a major axis and a minor axis. The major axis may be parallel to a fourth direction DR4 inclined with respect to the first direction DR1. The minor axis may be parallel to a fifth direction DR5 inclined with respect to the second direction DR2. For example, the fourth direction DR4 may be inclined with respect to the first direction DR1 by an angle of 45°, and the fifth direction DR5 may be inclined with respect to the second direction DR2 by an angle of 45°. The fourth direction DR4 may be orthogonal to the fifth direction DR5.

As an example of the present disclosure, the major axis of the respective first transmission hole TH1 is parallel to the transmission axis of the polarization layer POL (see FIG. 2), and the minor axis of the respective first transmission hole TH1 is parallel to the absorption axis of the polarization layer POL. In other words, the respective first transmission hole TH1 may have an elliptical shape elongating in a direction parallel to the transmission axis of the polarization layer POL.

In the meantime, the light receiving element OPD may have a shape (e.g., a square shape) in which a width in the fourth direction DR4 parallel to the transmission axis is the same as a width in the fifth direction DR5 perpendicular to the transmission axis.

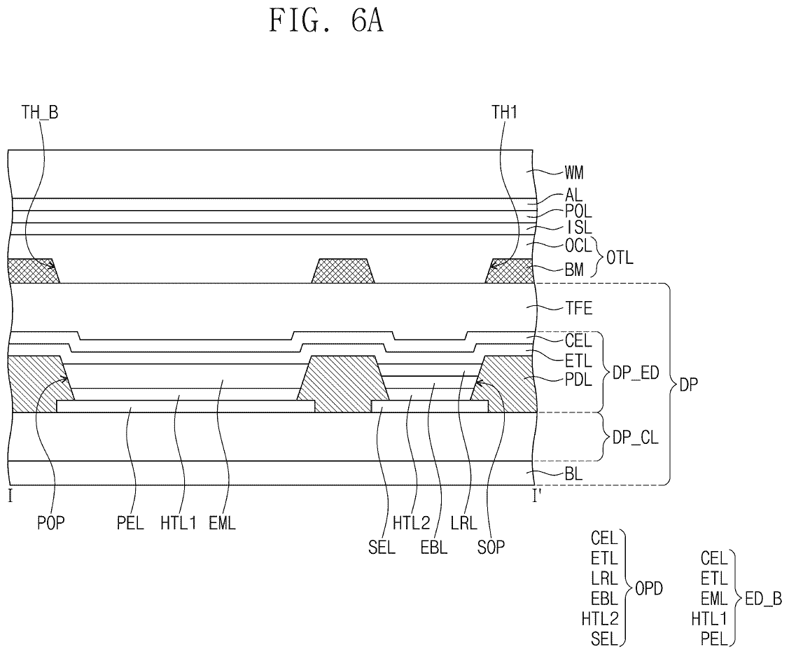

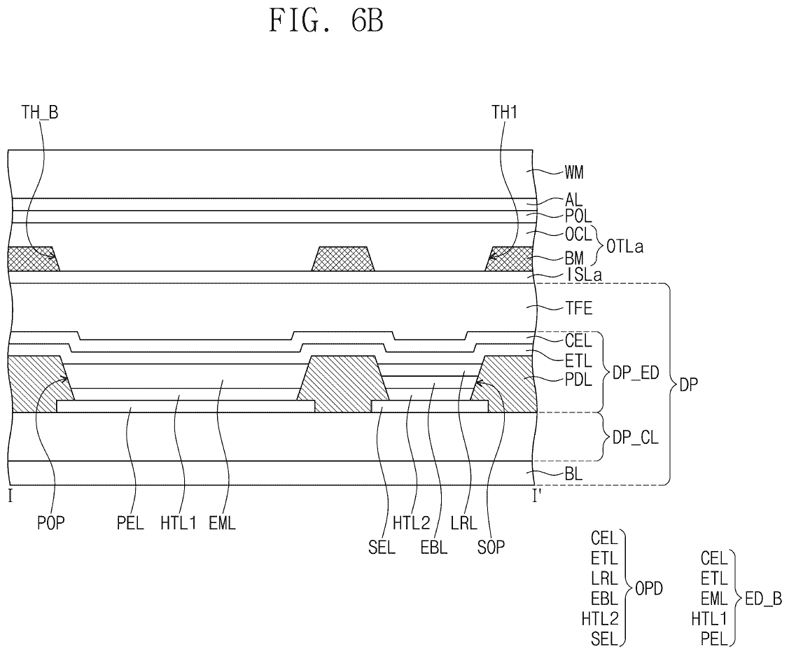

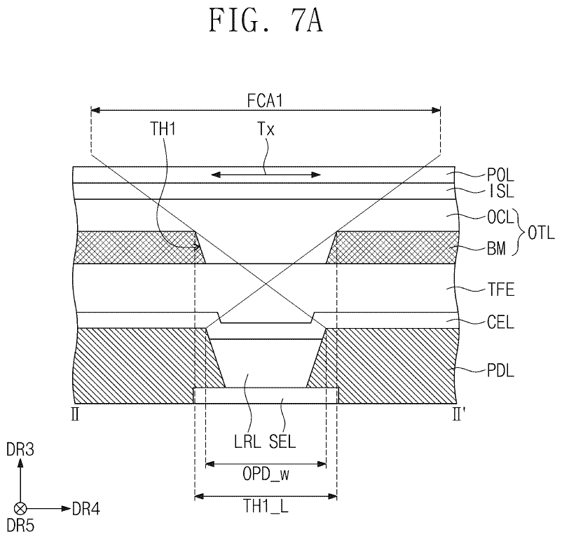

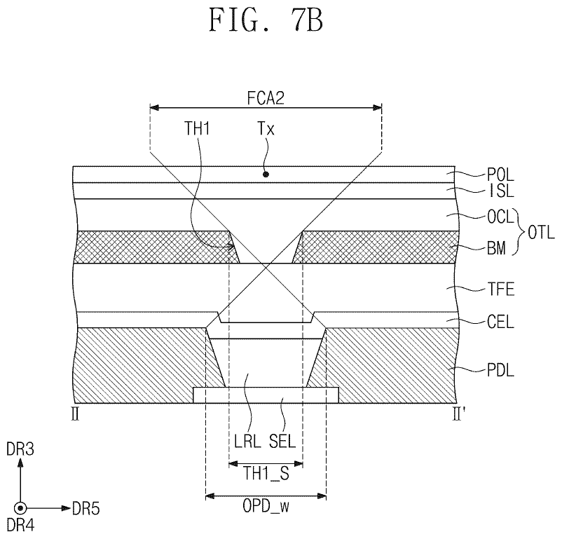

FIGS. 6A and 6B are cross-sectional views of a display device taken along a cutting line I-I′ illustrated in FIG. 5A, according to some embodiments of the present disclosure. FIG. 7A is a cross-sectional view of a display module taken along a cutting line II-II′ shown in FIG. 5B. FIG. 7B is a cross-sectional view of a display module taken along a cutting line III-III′ shown in FIG. 5B.

Referring to FIG. 6A, the display panel DP may include the base layer BL, the circuit layer DP_CL, the element layer DP_ED, and the encapsulation layer TFE.

The base layer BL may include a synthetic resin layer. The synthetic resin layer may include a thermosetting resin. In detail, the synthetic resin layer may be a polyimide-based resin layer, and the material thereof is not particularly limited thereto. The synthetic resin layer may include at least one of acrylate-based resin, methacrylate-based resin, polyisoprene, vinyl-based resin, epoxy-based resin, urethane-based resin, cellulose-based resin, siloxane-based resin, polyamide-based resin, or perylene-based resin. Besides, the base layer may include a glass substrate, a metal substrate, an organic/inorganic composite substrate, or the like.

At least one inorganic layer is formed on an upper surface of the base layer BL. The inorganic layer may include at least one of aluminum oxide, titanium oxide, silicon oxide, silicon oxynitride, zirconium oxide, or hafnium oxide. The inorganic layer may be formed of multiple layers.

The circuit layer DP_CL is located on the base layer BL. The circuit layer DP_CL may include the transistors T1 to T8 and the capacitor Cst of the pixel driving circuit P_PD illustrated in FIG. 4A. Moreover, the circuit layer DP_CL may include the transistors ST1 to ST3 of the sensor driving circuit O_SD shown in FIG. 4A.

The element layer DP_ED is located on the circuit layer DP_CL. The element layer DP_ED may include the light emitting elements ED_R, ED_B, ED_G1, and ED_G2 and the light receiving elements OPD. In FIG. 6A, the blue light emitting element ED_B and the light receiving element OPD are illustrated as examples, but the other light emitting elements ED_R, ED_G1, and ED_G2 may also have similar cross-sectional structures.

The blue light emitting element ED_B may include a pixel anode electrode PEL, a first hole transport layer HTL1, a light emitting layer EML, an electron transport layer ETL, and a common cathode electrode CEL. The light receiving element OPD may include a sensor anode electrode SEL, a second hole transport layer HTL2, an electron blocking layer EBL, a light receiving layer LRL, the electron transport layer ETL, and the common cathode electrode CEL.

Each of the pixel anode electrode PEL and the sensor anode electrode SEL may include a metallic material or a transparent conductive material. The pixel anode electrode PEL may be connected to a second electrode of the sixth transistor T6 shown in FIG. 4A. The sensor anode electrode SEL may be connected to the second electrode of the reset transistor ST1 shown in FIG. 4A.

A pixel defining film PDL may be provided on the circuit layer DP_CL on which the pixel anode electrode PEL and the sensor anode electrode SEL are formed. The pixel defining film PDL may define a pixel opening POP for exposing a part (e.g., a set or predetermined part) of the pixel anode electrode PEL, and a sensor opening SOP for exposing a part (e.g., a set or predetermined part) of the sensor anode electrode SEL. The blue light emitting element ED_B may have a shape corresponding to the shape of the pixel opening POP. That is, the shape of the blue light emitting element ED_B may be determined by the shape of the pixel opening POP. The light receiving element OPD may have a shape corresponding to the shape of the sensor opening SOP. That is, the shape of the light receiving element OPD may be determined by the shape of the sensor opening SOP. As an example of the present disclosure, the size of the pixel opening POP may be greater than the size of the sensor opening SOP.

The pixel defining film PDL may be an organic insulating layer made of organic materials. The organic materials may include acrylic resin, epoxy resin, phenolic resin, polyamide resin, polyimide resin, or the like. As an example of the present disclosure, the pixel defining film PDL may include a light absorbing material for absorbing light from the outside or may have a structure coated with a light absorbing agent. The light absorbing material may include a carbon-based black pigment. The light absorbing agent may include an opaque metal material such as chromium (Cr), molybdenum (Mo), an alloy (MoTi) of molybdenum and titanium, tungsten (W), vanadium (V), niobium (Nb), tantalum (Ta), manganese (Mn), cobalt (Co), or nickel (Ni), which has a high light absorption rate.

The first hole transport layer HTL1 is located on the pixel anode electrode PEL exposed through the pixel opening POP, and the light emitting layer EML is located on the first hole transport layer HTL1. Holes may move to the light emitting layer EML through the first hole transport layer HTL1. The light emitting layer EML may include an organic luminescent material and/or an inorganic luminescent material. The light emitting layer EML of the blue light emitting element ED_B may generate blue light. However, the color of light thus generated may vary depending on the type of a luminescent material included in the light emitting layer EML.

The second hole transport layer HTL2 is located on the sensor anode electrode SEL exposed through the sensor opening SOP, and the light receiving layer LRL is located on the second hole transport layer HTL2. Holes may move to the light receiving layer LRL through the second hole transport layer HTL2. The second hole transport layer HTL2 may include the same material as the first hole transport layer HTL1. However, the present disclosure is not limited thereto. The first and second hole transport layers HTL1 and HTL2 may include the same material or different materials depending on materials of the light emitting layer EML and the light receiving layer LRL.

As an example of the present disclosure, the electron blocking layer EBL may be placed between the second hole transport layer HTL2 and the light receiving layer LRL. The electron blocking layer EBL may block the charge of the light receiving layer LRL from moving to the second hole transport layer HTL2. Alternatively, the electron blocking layer EBL may be omitted.

The light receiving layer LRL may sense the intensity of light by emitting electrons in response to light of a specific wavelength band. The light receiving layer LRL may include a low-molecular-weight organic material or a high-molecular-weight organic material.

The electron transport layer ETL may be provided on the light emitting layer EML and the light receiving layer LRL. The electron transport layer ETL may be directly provided to the plurality of pixels PX (see FIG. 3) and the plurality of sensors FX (see FIG. 3). Although not shown in FIG. 6A, functional layers such as a hole injection layer and an electron injection layer may be added to the element layer DP_ED.

The common cathode electrode CEL may be provided on the electron transport layer ETL. The common cathode electrode CEL may be commonly provided to the plurality of pixels PX and the plurality of sensors FX. The common cathode electrode CEL may include a transparent conductive material.

The encapsulation layer TFE may be located on the element layer DP_ED. The encapsulation layer TFE may include an inorganic layer, an organic layer, and an inorganic layer that are sequentially stacked. The inorganic layers may include inorganic materials and may protect the pixels from moisture/oxygen. The organic layer may include organic materials and may protect the pixels PX and the sensor FX from foreign objects such as dust particles.

The optical layer OTL may be provided on the encapsulation layer TFE. The optical layer OTL may include a black matrix BM and an overcoat layer OCL. The black matrix BM may absorb or block light introduced from the outside. The black matrix BM may include an organic light-shielding material. For example, the organic light-shielding material may include, but is not limited to, one of carbon black and titanium black. The black matrix BM may be placed to overlap the pixel defining film PDL.

A plurality of transmission holes may be provided on the optical layer OTL by the black matrix BM. FIG. 6A illustrates the first transmission hole TH1 formed to correspond to the light receiving element OPD and the 2-2nd transmission hole TH_B formed to correspond to the blue light emitting element ED_B among the plurality of transmission holes. The size of the 2-2nd transmission hole TH_B may be greater than the size of the first transmission hole TH1.

The overcoat layer OCL may be provided to cover the black matrix BM and the encapsulation layer TFE exposed through the plurality of transmission holes. The overcoat layer OCL may include an organic insulating material. The overcoat layer OCL may be provided with a thickness sufficient to remove a step between the black matrix BM and the encapsulation layer TFE. A material of the overcoat layer OCL may not be particularly limited as long as the material is capable of planarizing an upper surface of the optical layer OTL with a given thickness and may include, for example, an acrylate-based organic material.

The input sensing layer ISL may be located on the overcoat layer OCL, and the polarization layer POL may be located on the input sensing layer ISL. However, the present disclosure is not limited thereto. As shown in FIG. 6B, an input sensing layer ISLa may be directly located on the encapsulation layer TFE, and an optical layer OTLa may be provided on the input sensing layer ISLa. A configuration of the optical layer OTLa is the same as a configuration of the optical layer OTL illustrated in FIG. 6A, and thus redundant description is omitted.

Referring to FIGS. 6A to 7B, the polarization layer POL may be located on the input sensing layer ISL or the optical layer OTLa. The polarization layer POL may include a transmission axis Tx and an absorption axis orthogonal to the transmission axis Tx. As an example of the present disclosure, the transmission axis Tx of the polarization layer POL may be parallel to the fourth direction DR4 and perpendicular to the fifth direction DR5.

A short axis TH1_S of the first transmission hole TH1 may be perpendicular to the transmission axis Tx of the polarization layer POL, and a long axis TH1_L of the first transmission hole TH1 may be parallel to the transmission axis Tx of the polarization layer POL. Accordingly, a width of the first transmission hole TH1 in the fifth direction DR5, which is perpendicular to the transmission axis Tx of the polarization layer POL, may be smaller than a width of the first transmission hole TH1 in the fourth direction DR4, which is parallel to the transmission axis Tx of the polarization layer POL.

Meanwhile, the light receiving element OPD may have the same width OPD_w in the fourth and fifth directions DR4 and DR5. Even when the light receiving element OPD has the same width OPD_w in the fourth and fifth directions DR4 and DR5, widths of fingerprint areas that the light receiving element OPD is capable of obtaining in the fourth and fifth directions DR4 and DR5 may be different from each other depending on the shape of the first transmission hole TH1.

The width of the fingerprint area (hereinafter, referred to as a “first fingerprint capture area FCA1”) that the light receiving element OPD is capable of obtaining in the fourth direction DR4 is referred to as a “first width”. The width of the fingerprint area (hereinafter, referred to as a “second fingerprint capture area FCA2”) that the light receiving element OPD is capable of obtaining in the fifth direction DR5 is referred to as a “second width”. As an example of the present disclosure, the second width may be smaller than the first width.

When the width of the second fingerprint capture area FCA2 of the light receiving element OPD in the fifth direction DR5, which is perpendicular to the transmission axis Tx of the polarization layer POL, is reduced, light (i.e., noise light) reflected from a peripheral area in the fifth direction DR5 may be blocked from being incident on the light receiving element OPD. In other words, when the width of the second fingerprint capture area FCA2 is narrowed, noise light may be removed, and thus the light receiving element OPD may clearly receive light having different pieces of intensity for valleys and ridges of a fingerprint. As a result, the light receiving element OPD may obtain a clear fingerprint image for a fingerprint parallel to the transmission axis Tx.

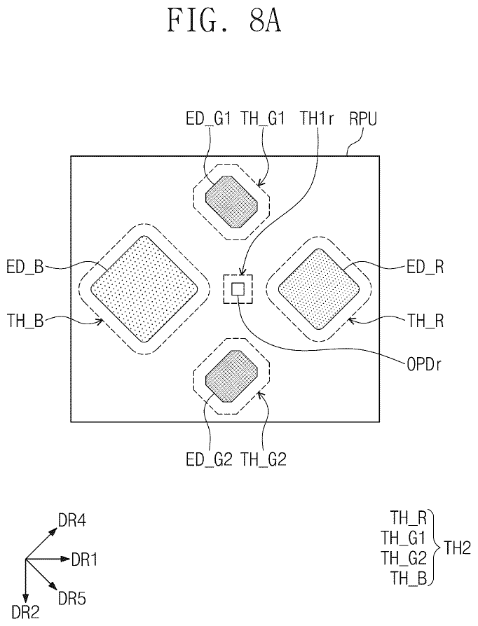

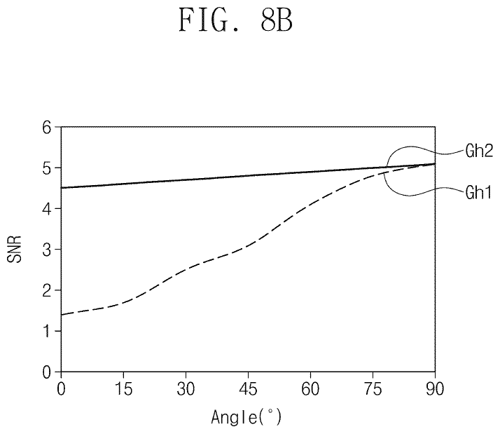

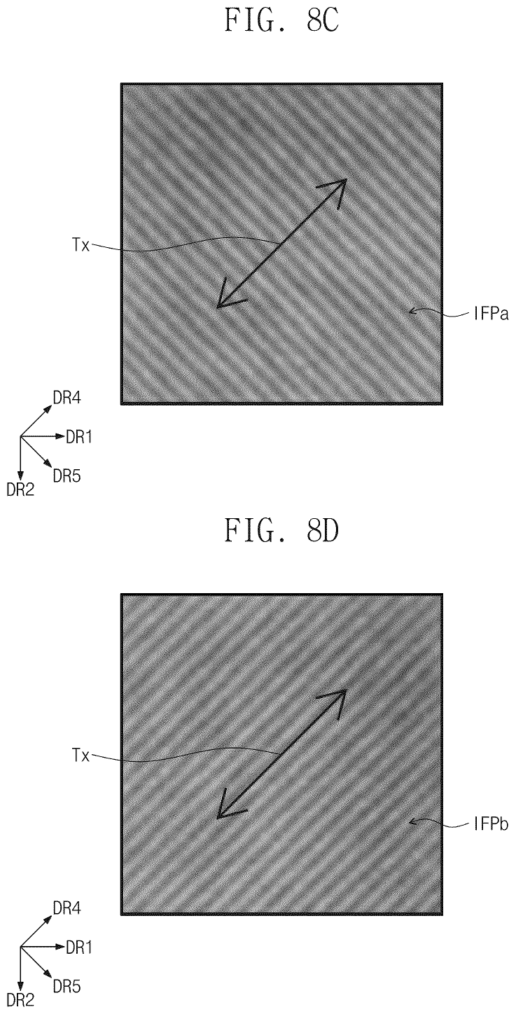

FIG. 8A is a plan view showing a first transmission hole shape of an optical layer according to a comparative example. FIG. 8B is a graph showing a signal-to-noise ratio according to an angle between an extension direction of a fake fingerprint and a transmission axis of a polarization layer. FIG. 8C is a diagram showing a fake fingerprint image perpendicular to a transmission axis of a polarization layer, according to some embodiments of the present disclosure. FIG. 8D is a drawing showing a fake fingerprint image parallel to a transmission axis of a polarization layer, according to some embodiments of the present disclosure.

In FIG. 8B, an x-axis indicates an angle between the transmission axis and the extension direction of a fake fingerprint, and a y-axis indicates a signal-to-noise ratio SNR. In FIG. 8A, a first graph Gh1 is a graph showing the signal-to-noise ratio SNR measured when an optical layer has a first transmission hole TH1r according to a comparative example, and a second graph Gh2 is a graph showing the signal-to-noise ratio SNR measured when the optical layer according to some embodiments of the present disclosure has the first transmission hole TH1 illustrated in FIG. 5B.

Referring to FIGS. 8A and 8B, according to a comparative example, the first transmission hole TH1r of the optical layer may have the same shape (e.g., a square shape) as a light receiving element OPDr. In this case, the first transmission hole TH1r may have a structure in which a width in the fourth direction DR4 parallel to the transmission axis Tx (see FIG. 7A) of the polarization layer POL (see FIG. 7A) is the same as a width in the fifth direction DR5 perpendicular to the transmission axis Tx.

As in the comparative example, when the width of the first transmission hole TH1r perpendicular to the transmission axis Tx of the polarization layer POL is not narrower than the width of the first transmission hole TH1r parallel to the transmission axis Tx, the signal-to-noise ratio SNR for a fingerprint extending in a direction perpendicular to the transmission axis Tx may decrease compared to the signal-to-noise ratio SNR for the fingerprint extending in the direction parallel to the transmission axis Tx. That is, as shown in the first graph Gh1, when the signal-to-noise ratio SNR decreases, a relatively blurry fingerprint image may be obtained.

As shown in FIG. 5B, when the width of the first transmission hole TH1 is narrowed in the fifth direction DR5 perpendicular to the transmission axis Tx, noise light in the fifth direction DR5 may be blocked from being incident on the respective light receiving elements OPD. In other words, when the width of the first transmission hole TH1 is narrowed in the fifth direction DR5 perpendicular to the transmission axis Tx, a difference in intensity of light reflected from valleys and ridges of a fingerprint that appear repeatedly in a direction perpendicular to the transmission axis Tx may clearly be seen. As a result, the signal-to-noise ratio SNR for the fingerprint extending in the direction parallel to the transmission axis Tx may be increased. As a result, the light receiving element OPD may obtain a relatively clear fingerprint image even for the fingerprint extending in the direction parallel to the transmission axis Tx.

That is, as illustrated in the second graph Gh2 in FIG. 8B, even when an angle between an extension direction of a fake fingerprint and the transmission axis Tx of the polarization layer POL changes, the overall uniform signal-to-noise ratio SNR may be obtained. Accordingly, the biometric information recognition performance (e.g., fingerprint recognition rate) of the display device DD (see FIG. 3) may be relatively improved.

FIG. 8C illustrates a fake fingerprint image IFPa where the extension direction of the fake fingerprint is perpendicular to the transmission axis Tx. FIG. 8D illustrates a fake fingerprint image IFPb where the extension direction of the fake fingerprint is parallel to the transmission axis Tx. When the fake fingerprint extends in the fifth direction DR5 perpendicular to the transmission axis Tx in the fake fingerprint image IFPa, the light receiving element OPD may be relatively less affected by reflected light, and thus a clear fingerprint image may be obtained. In the meantime, when the fake fingerprint in the fake fingerprint image IFPb extends in the fourth direction DR4 parallel to the transmission axis Tx, the light receiving element OPD may be greatly affected by the reflected light. However, as shown in FIG. 5B, when the width of the first transmission hole TH1 in the fifth direction DR5 is reduced compared to the width of the first transmission hole TH1 in the fourth direction DR4, the light receiving element OPD may be less affected by reflected light, and thus the light receiving element OPD may obtain a clear fingerprint image even for a fake fingerprint extending to be parallel to the transmission axis Tx.

Accordingly, the reliability of the sensor FX (see FIG. 3) may be relatively improved, and the biometric information recognition performance (e.g., fingerprint recognition rate) of the display device DD (see FIG. 3) may be relatively improved.

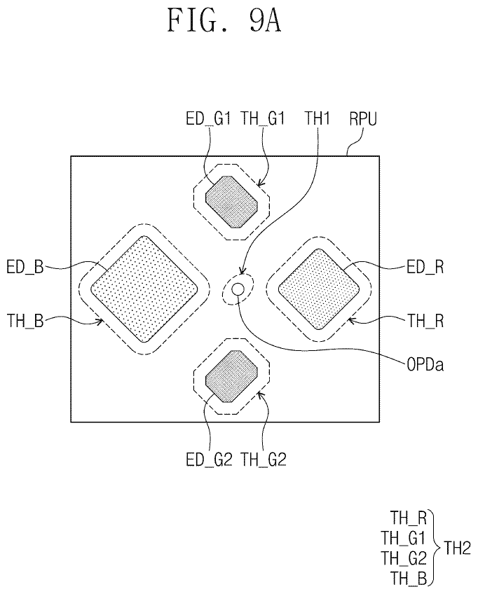

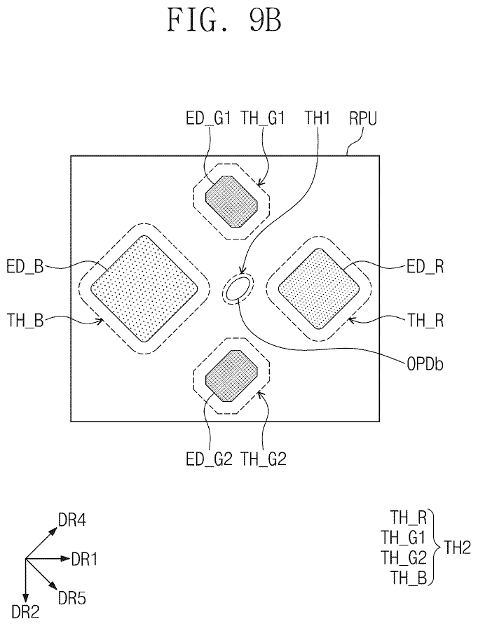

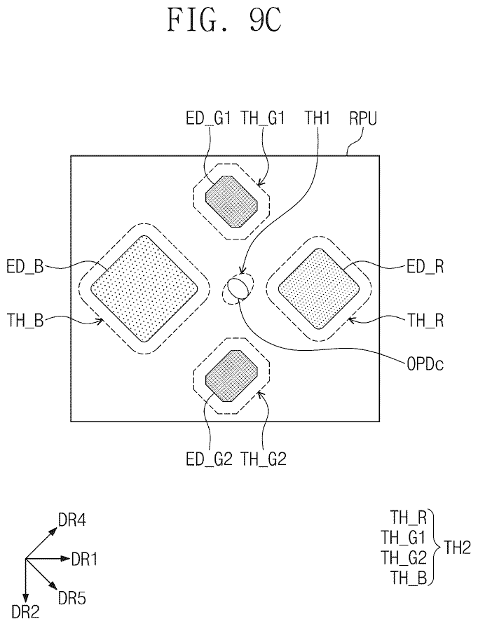

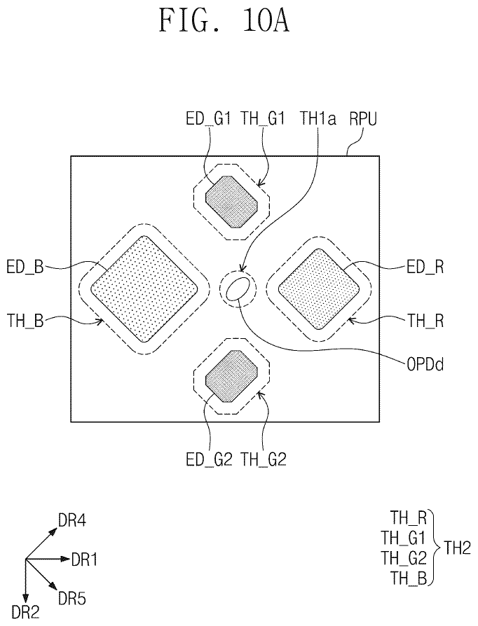

FIGS. 9A to 9C are plan views showing shapes of a light receiving element and a first transmission hole, according to embodiments of the present disclosure. However, the same reference numerals are given to the same components as those shown in FIG. 5B among the components shown in FIGS. 9A to 9C, and thus a detailed description thereof will be omitted.

Referring to FIG. 9A, a light receiving element OPDa may have a shape (e.g., a circle shape) in which a width in the fourth direction DR4 parallel to the transmission axis Tx (see FIG. 7A) of the polarization layer POL (see FIG. 2) is the same as a width in the fifth direction DR5 perpendicular to the transmission axis Tx.

The first transmission hole TH1 may provide a passage through which external light is incident onto the light receiving element OPDa. The first transmission hole TH1 may have a shape the same as or different from a shape of the light receiving element OPDa. As an example of the present disclosure, in FIG. 9A, the first transmission hole TH1 has a different shape from the shape of the light receiving element OPDa. For example, the first transmission hole TH1 may have an elliptical shape.

As an example of the present disclosure, the long axis of the first transmission hole TH1 is parallel to the transmission axis Tx of the polarization layer POL, and the short axis of the first transmission hole TH1 is perpendicular to the transmission axis Tx of the polarization layer POL. In other words, the first transmission hole TH1 may have an elliptical shape elongating in a direction parallel to the transmission axis Tx of the polarization layer POL.

That is, the light receiving element OPDa of a circular shape may have the same width in the fourth and fifth directions DR4 and DR5. However, even when the light receiving element OPDa has the same width in the fourth and fifth directions DR4 and DR5, widths of fingerprint areas that the light receiving element OPDa is capable of obtaining in the fourth and fifth directions DR4 and DR5 may be different from each other depending on the shape of the first transmission hole TH1.

When the width of the first transmission hole TH1 in the fifth direction DR5 perpendicular to the transmission axis Tx of the polarization layer POL is reduced, light (i.e., noise light) reflected from a peripheral area in the fifth direction DR5 may be blocked from being incident on the light receiving element OPDa. In other words, the light receiving element OPDa may clearly receive light having different intensity for valleys and ridges of a fingerprint because the noise light is removed. As a result, the light receiving element OPDa may obtain a clear fingerprint image for a fingerprint that is parallel to the transmission axis Tx.

Referring to FIG. 9B, a light receiving element OPDb has the same shape as the first transmission hole TH1. For example, each of the first transmission hole TH1 and the light receiving element OPDb may have an elliptical shape. The light receiving element OPDb may have a long axis and a short axis. The long axis may be parallel to the fourth direction DR4, which is parallel to the transmission axis Tx of the polarization layer POL (see FIG. 2). The short axis may be parallel to the fifth direction DR5, which is perpendicular to the transmission axis Tx of the polarization layer POL.

Likewise, the long axis of the first transmission hole TH1 is parallel to the transmission axis Tx of the polarization layer POL, and the short axis of the first transmission hole TH1 is perpendicular to the transmission axis Tx of the polarization layer POL. In other words, each of the first transmission hole TH1 and the light receiving element OPDb may have an elliptical shape elongating in a direction parallel to the transmission axis Tx of the polarization layer POL.

When the width of the light receiving element OPDb is reduced in the fifth direction DR5, which is perpendicular to the transmission axis Tx of the polarization layer POL, even though there is light reflected from a peripheral area (i.e., noise light) in the fifth direction DR5, the reflected light may be less incident on the light receiving element OPDb. In other words, the light receiving element OPDb is less affected by the noise light, and thus the light receiving element OPDb may obtain a clear fingerprint image for a fingerprint parallel to the transmission axis Tx.

Referring to FIG. 9C, a light receiving element OPDc has a different shape from the shape of the first transmission hole TH1. For example, the first transmission hole TH1 may have an elliptical shape elongating in the fourth direction DR4 parallel to the transmission axis Tx (see FIG. 7A) of the polarization layer POL (see FIG. 2), and the light receiving element OPDc may have an elliptical shape elongating in the fifth direction DR5 perpendicular to the transmission axis Tx of the polarization layer POL.

The long axis of the light receiving element OPDc may be perpendicular to the transmission axis Tx of the polarization layer POL, and the short axis of the light receiving element OPDc may be parallel to the transmission axis Tx of the polarization layer POL. The long axis of the first transmission hole TH1 may be parallel to the transmission axis Tx of the polarization layer POL, and the short axis of the first transmission hole TH1 may be perpendicular to the transmission axis Tx of the polarization layer POL.

As an example of the present disclosure, a ratio (hereinafter, referred to as a “first ratio”) of the long axis to the short axis of the light receiving element OPDc may be different from a ratio (hereinafter, referred to as a “second ratio”) of the long axis to the short axis of the first transmission hole TH1. For example, the first ratio may be smaller than the second ratio. Even in this case, when the first transmission hole TH1 is formed more asymmetrically than the light receiving element OPDc, the light receiving element OPDc may obtain a clear fingerprint image for the fingerprint parallel to the transmission axis Tx.

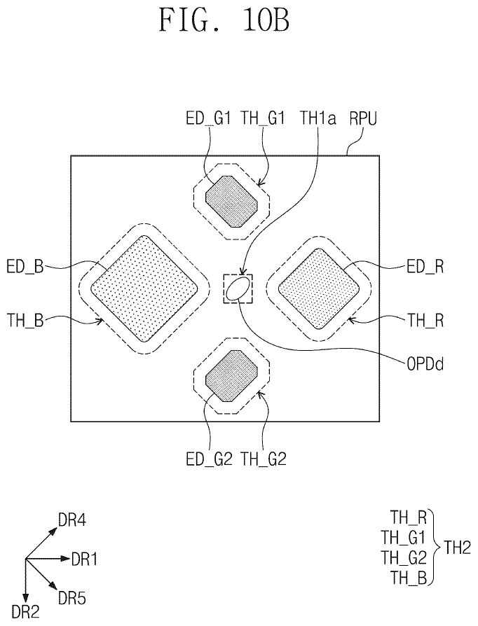

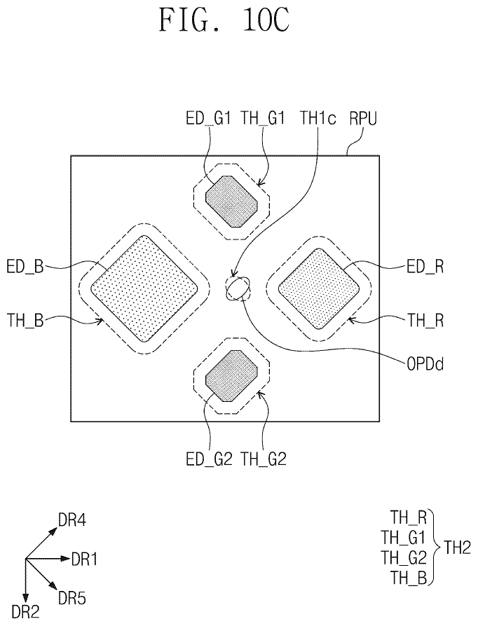

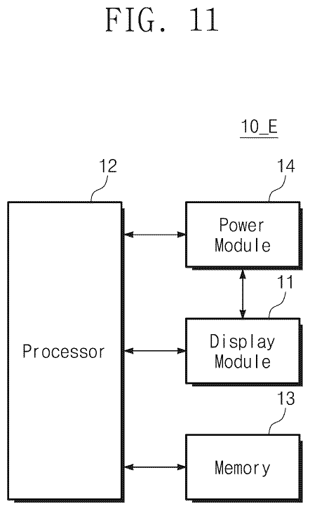

FIGS. 10A to 10C are plan views showing shapes of a light receiving element and a first transmission hole, according to embodiments of the present disclosure.

Referring to FIGS. 10A and 10B, a light receiving element OPDd may have a shape (e.g., an elliptical shape) in which a width in the fourth direction DR4 parallel to the transmission axis Tx (see FIG. 7A) of the polarization layer POL (see FIG. 2) is different from a width in the fifth direction DR5 perpendicular to the transmission axis Tx.

The first transmission hole TH1a or TH1b may provide a passage through which external light is incident onto the light receiving element OPDd. The first transmission hole TH1a or TH1b may have a shape the same as or different from a shape of the light receiving element OPDd. As an example of the present disclosure, in FIGS. 10A and 10B, the first transmission hole TH1a or TH1b has a different shape from the shape of the light receiving element OPDd.

As an example of the present disclosure, the first transmission hole TH1a or TH1b may have a shape (e.g., a circular shape or a square shape) in which the width in the fourth direction DR4 parallel to the transmission axis Tx of the polarization layer POL is the same as the width in the fifth direction DR5 perpendicular to the transmission axis Tx.

That is, even when the first transmission hole TH1a or TH1b have the same widths in the fourth and fifth directions DR4 and DR5, widths of the fingerprint areas that the light receiving element OPDd is capable of obtaining in the fourth and fifth directions DR4 and DR5 may be different from each other due to the light receiving element OPDd of the elliptical shape.

Even though the first transmission hole TH1a or TH1b has the same width in the fourth and fifth directions DR4 and DR5, when the width of the light receiving element OPDd in the fifth direction DR5 is reduced, the width of the obtainable fingerprint area in the fifth direction DR5 may be reduced. Accordingly, light (i.e., noise light) reflected from a peripheral area in the fifth direction DR5 may be blocked from being incident on the light receiving element OPDd. In other words, a fingerprint image obtained by the light receiving element OPDd may be prevented from being blurred by the noise light.

Referring to FIG. 10C, the light receiving element OPDd has a different shape from the shape of the first transmission hole TH1c. For example, the light receiving element OPDd may have an elliptical shape elongating in the fourth direction DR4 parallel to the transmission axis Tx (see FIG. 7A) of the polarization layer POL (see FIG. 2), and the first transmission hole TH1c may have an elliptical shape elongating in the fifth direction DR5 perpendicular to the transmission axis Tx of the polarization layer POL.

The long axis of the light receiving element OPDd may be parallel to the transmission axis Tx of the polarization layer POL, and the short axis of the light receiving element OPDd may be perpendicular to the transmission axis Tx of the polarization layer POL. The long axis of the first transmission hole TH1c may be parallel to the transmission axis Tx of the polarization layer POL, and the short axis of the first transmission hole TH1c may be perpendicular to the transmission axis Tx of the polarization layer POL.

As an example of the present disclosure, a ratio (hereinafter, referred to as a “first ratio”) of the long axis to the short axis of the light receiving element OPDd may be different from a ratio (hereinafter, referred to as a “second ratio”) of the long axis to the short axis of the first transmission hole TH1c. For example, the second ratio may be smaller than the first ratio. Even in this case, the light receiving element OPDd may obtain a clear fingerprint image for the fingerprint parallel to the transmission axis Tx by forming the light receiving element OPDd more asymmetrically than the first transmission hole TH1.

A display device according to some embodiments may be applied to various electronic devices. An electronic device according to some embodiments may include the display device described above and may further include modules or devices having other additional functions.

FIG. 11 is a block diagram of an electronic device according to some embodiments.

Referring to FIG. 11, the electronic device 10_E according to some embodiments may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), or a controller.

Data information required for operation of the processor 12 or the display module 11 may be stored in the memory 13. When the processor 12 executes an application stored in the memory 13, an image data signal and/or an input control signal may be transferred to the display module 11, and the display module 11 may process the provided signal and may output image information through a display screen.

The power module 14 may include a power supply module, such as a power adaptor or a battery device, and a power conversion module that converts power supplied by the power supply module and generates power required for operation of the electronic device 10_E.

At least one of the components of the electronic device 10_E described above may be included in the display device according to the embodiments described above. In addition, some of the separate modules functionally included in one module may be included in the display device, and the others may be provided separately from the display device. For example, the display device may include the display module 11, and the processor 12, the memory 13, and the power module 14 may be provided in the form of other devices within the electronic device 10_E rather than the display device.

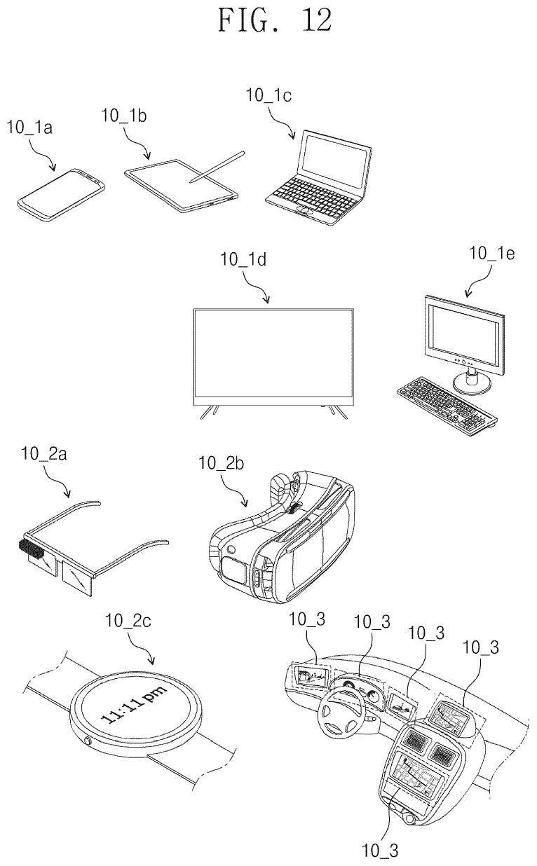

FIG. 12 illustrates schematic views of electronic devices according to various embodiments.

Referring to FIG. 14, various electronic devices, to which the display device according to the embodiments is applied, may include not only an electronic device for displaying an image, such as a smart phone 10_1a, a tablet PC 10_1b, a laptop computer 10_1c, a TV 10_1d, or a desk monitor 10_1e, but also a wearable electronic device, such as smart glasses 10_2a, a head mounted display 10_2b, or a smart watch 10_2c, which includes a display module, and a vehicle electronic device 10_3, such as a center information display (CID) located on an instrument panel, a center fascia, or a dashboard of a vehicle or a room mirror display, which includes a display module.

Although aspects of some embodiments of the present disclosure have been described for illustrative purposes, those skilled in the art will appreciate that various modifications, and substitutions are possible, without departing from the scope and spirit of the present disclosure as disclosed in the accompanying claims. Accordingly, the technical scope of the present disclosure is not limited to the detailed description of this specification, but should be defined by the claims.

As described above, when the width of a fingerprint capture area of a light receiving element is reduced in a direction perpendicular to a transmission axis of a polarization layer, light (i.e., noise light) reflected from a peripheral area may be blocked from entering the light receiving element. In other words, when the width of the fingerprint capture area is narrowed, the light receiving element may clearly receive light having different intensity for valleys and ridges of a fingerprint because the noise light is removed. As a result, the light receiving element may obtain a clear fingerprint image for a fingerprint that is parallel to the transmission axis.

Accordingly, even when an angle between an extension direction of the fingerprint and the transmission axis of the polarization layer changes, an overall uniform signal-to-noise ratio may be obtained. Accordingly, the biometric information recognition performance (e.g., fingerprint recognition rate) of a display device may be relatively improved.

While aspects of some embodiments of the present disclosure have been described with reference to embodiments thereof, it will be apparent to those of ordinary skill in the art that various changes and modifications may be made thereto without departing from the spirit and scope of embodiments according to the present disclosure as set forth in the following claims, and their equivalents.

What is claimed is:

1. A display device comprising:
a base layer;
a circuit layer on the base layer;
an element layer on the circuit layer and including a light emitting element and a light receiving element;
an optical layer on the element layer and having a first transmission hole corresponding to the light receiving element; and
a polarization layer on the optical layer and configured to have a transmission axis,
wherein the first transmission hole has a shape in which a width in a direction perpendicular to the transmission axis is smaller than a width in a direction parallel to the transmission axis.

2. The display device of claim 1, wherein the light receiving element has a shape different from a shape of the first transmission hole.

3. The display device of claim 2, wherein the first transmission hole has an elliptical shape including a long axis parallel to the transmission axis and a short axis perpendicular to the transmission axis.

4. The display device of claim 3, wherein the light receiving element has a shape in which a width in the direction parallel to the transmission axis is the same as a width in the direction perpendicular to the transmission axis.

5. The display device of claim 4, wherein the light receiving element has a square shape or a circular shape.

6. The display device of claim 3, wherein the light receiving element has a shape including a long axis perpendicular to the transmission axis and a short axis parallel to the transmission axis.

7. The display device of claim 6, wherein a ratio between the long axis of the light receiving element and the short axis of the light receiving element is different from a ratio between the long axis of the first transmission hole and the short axis of the first transmission hole.

8. The display device of claim 1, wherein the light receiving element has a same shape as the first transmission hole.

9. The display device of claim 8, wherein the first transmission hole has a long axis parallel to the transmission axis and a short axis perpendicular to the transmission axis, and
wherein the light receiving element has a shape including a long axis parallel to the transmission axis and a short axis perpendicular to the transmission axis.

10. The display device of claim 9, wherein a ratio between the long axis of the light receiving element and the short axis of the light receiving element is equal to a ratio between the long axis of the first transmission hole and the short axis of the first transmission hole.

11. The display device of claim 8, wherein each of the first transmission hole and the light receiving element has an elliptical shape elongated in the direction parallel to the transmission axis.

12. The display device of claim 1, further comprising:
an encapsulation layer interposed between the optical layer and the element layer,
wherein the optical layer is on the encapsulation layer and includes a light-shielding material.

13. The display device of claim 1, wherein the optical layer further includes:
a second transmission hole corresponding to the light emitting element, and
wherein the second transmission hole has a shape the same as the light emitting element.

14. The display device of claim 1, further comprising:
an input sensing layer interposed between the optical layer and the polarization layer.

15. A display device comprising:
a base layer;
a circuit layer on the base layer;
an element layer on the circuit layer and including a light emitting element and a light receiving element;
an optical layer on the element layer and provided with a first transmission hole corresponding to the light receiving element; and
a polarization layer on the optical layer and configured to have a transmission axis,
wherein the light receiving element has a shape in which a width in a direction perpendicular to the transmission axis is smaller than a width in a direction parallel to the transmission axis.

16. The display device of claim 15, wherein the light receiving element has a shape different from a shape of the first transmission hole.

17. The display device of claim 16, wherein the light receiving element has an elliptical shape including a long axis parallel to the transmission axis and a short axis perpendicular to the transmission axis.

18. The display device of claim 17, wherein the first transmission hole has a shape in which a width in the direction parallel to the transmission axis is the same as a width in the direction perpendicular to the transmission axis.

19. The display device of claim 17, wherein the first transmission hole has a shape including a long axis perpendicular to the transmission axis and a short axis parallel to the transmission axis, and
wherein a ratio between the long axis of the first transmission hole and the short axis of the first transmission hole is different from a ratio between the long axis of the light receiving element and the short axis of the light receiving element.

20. An electronic device comprising:
a display module; and
a processor configured to control operation of the display module,
wherein the display module includes:
a base layer;
a circuit layer on the base layer;
an element layer on the circuit layer and including a light emitting element and a light receiving element;
an optical layer on the element layer and having a first transmission hole corresponding to the light receiving element; and
a polarization layer on the optical layer and configured to have a transmission axis,
wherein the first transmission hole has a shape in which a width in a direction perpendicular to the transmission axis is smaller than a width in a direction parallel to the transmission axis.
